(19) United States
(12) Patent Application Publication
(10) Pub. No.: US 2019/0284334 A1
(43) Pub. Date: Sep. 19, 2019

(54) POLY (SPIROBIFLUORENE) AND ORGANIC ELECTROLUMINESCENT DEVICE

(71) Applicant: Changchun Institute of Applied Chemistry, Chinese Academy of Science, Jilin Province (CN)

(72) Inventors: Lixiang Wang, Jilin Province (CN); Junqiao Ding, Jilin Province (CN); Keyan Bai, Jilin Province (CN); Lei Zhao, Jilin Province (CN)

(21) Appl. No.: 16/347,741

(22) PCT Filed: Nov. 10, 2016
(86) PCT No.: PCT/CN2016/105368

§ 371 Date: May 6, 2019

(51) Int. Cl. C08G 61/12; H01L 51/50; H01L 51/00

(52) U.S. Cl. CPC C08G 61/124; H01L 51/0039; H01L 51/5012

(57) ABSTRACT

The present disclosure provides a poly(spirobifluorene) having a structure represented by Formula (I). In the present disclosure, a polymer containing carbazolyl spirobifluorene is synthesized by introducing a carbazolyl group at a side chain of a spirobifluorene. No intramolecular charge transfer from a main chain to a side chain occurs in the carbazolyl spirobifluorene polymer prepared in the present disclosure. And the polymer has a good hole transport capability due to the modification with carbazole, and a good device efficiency can be achieved while retaining the advantage of the color purity of pure blue light. Meanwhile, by introducing an aromatic group to the poly(spirobifluorene) of the present disclosure, emission of three primary colors of blue, green and red can be obtained, and a good device efficiency can be achieved.

### TECHNICAL FIELD

The present disclosure relates to the field of polymer preparation method, and in particular to a poly(spirobifluorene) and an organic electroluminescent device.

### BACKGROUND

Polymer light-emitting diodes (PLED) have advantages of low cost, easiness to achieve a large area, flexible display and the like because they can be prepared by solution processing (such as ink printing and spray coating), and thus are highly favored in the luminescence field. Current blue light polymer materials are mostly polymers such as polyparaphenylene (PPP), polycarbazole (PCz), and polyfluorene (PF). Among them, polyfluorene and derivatives thereof are widely regarded as outstanding ones of these materials, and have been reported in numerous literatures and patents. Additional primary colors of red and green can be produced by copolymerizing a blue polyfluorene derivative as the backbone with other monomers, so as to achieve a full color display device.

However, polyfluorene suffers from a problem that it is liable to produce fluorenone and excimer. In prior art, good results are achieved by processes such as introducing a unit with large steric hindrance at 9,9 site of fluorene or copolymerizing fluorene with another unit to transfer energy or the like. Another approach to completely solve the problem of polyfluorene stability is to connect 9,9 sites of two fluorenes via a “spiral” structure. In this way, not only the fluorenone-producing site is eliminated, but also a larger spatial structure of the spiral structure is not liable to aggregation. With respect to the structure, poly(spirobifluorene) retains the conjugate structure of polyfluorene, completely with “fluorene” as the repeating unit, so that it has excellent spectral properties of polyfluorene, and becomes a potential alternative material for polyfluorene.

Poly(spirobifluorene) itself has a poor solubility, and cannot be used in solution processing. Therefore, a solubilizing side chain unit is required. The side chain unit commonly used in prior art is an alkoxy chain or an alkyl chain. After investigation, it has been discovered that poly(spirobifluorene) has a “spiroconjugation” effect. For example, Hintschich (Journal of Physical Chemistry B, 2008, 112, 16300-16306), Wu (Applied Physics Letters, 2005, 87) and Kim (Journal of Luminescence, 2005, 115, 109-116), Wang (Polym Chem, 2014, 5, 6444), etc. report that the alkoxy chain at the side chain of poly(spirobifluorene) has a strong electron-donating effect, resulting in charge transfer from the main chain to the side chain, which in turn leads to adverse factors such as red shift of the polymer's spectrum, reduced fluorescence quantum efficiency, and prolonged fluorescence lifetime. To date, how to eliminate such charge transfer in a modified poly(spirobifluorene) is yet not reported.

### SUMMARY

In this regard, the technical problem to be solved by the present invention is to provide a poly(spirobifluorene) without intramolecular charge transfer from a main chain to a side chain, while the use of the poly(spirobifluorene) of the present invention as a luminescent material in a luminescent device enables a high device efficiency.

The present disclosure provides a poly(spirobifluorene) comprising more than 50% proportion of a repeating unit represented by Formula (I):

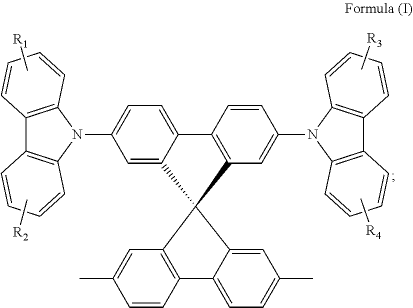

wherein R₁, R₂, R₃ and R₄ are independently selected from the group consisting of a C1˜C22 alkyl, a C1˜C22 alkoxy and a C1˜C22 heteroalkyl.

Preferably, the alkyl, alkoxy, and heteroalkyl may be optionally substituted with a substituent selected from the group consisting of —OH, —SH, —SiH₃, —SiH₂Rₐ, —SiHRₐR_{b}, —SiRₐR_{b}R_{c}, R_{d}NH—, R_{d}RₑN—, NH₂—, a C1˜C15 alkylsulfanyl, —CO—OR_{f} and halogen; wherein the heteroalkyl contains a heteroatom of O, N, S or Si;
wherein Rₐ, R_{b}, R_{c}, R_{d}, Rₑ, and R_{f} are independently selected from the group consisting of a C1˜C22 alkyl, a C3˜C22 alkoxy, and a C1˜C22 heteroalkyl containing a heteroatom of O, N, S or Si.

Preferably, R₁, R₂, R₃ and R₄ are independently selected from the group consisting of a C3˜C15 alkyl, a C3˜C15 alkoxy and a C3˜C15 heteroalkyl.

Preferably, the poly(spirobifluorene) further comprises a repeating unit represented by Formula (II):

—Ar— Formula (II);
wherein Ar is selected from one or more of a C6˜C60 aryl and a C6˜C60 heteroaryl.

Preferably, the aryl and heteroaryl may be optionally substituted with a substituent selected from the group consisting of H, halogen, —OH, —SH, —CN, —NO₂, a C1˜C15 alkylsulfanyl, a C1˜C40 alkyl and a C1˜C40 substituted alkyl; and
the heteroaryl contains a heteroatom independently selected from the group consisting of Si, Ge, N, P, O, S and Se.

Preferably, the aryl is selected from the group consisting of a monocyclic aryl, and combinations formed by connecting a plurality of aryls via any one or more of single bond, —C—C—, —C═C—, —C═N—, —C═P—, —C≡C,

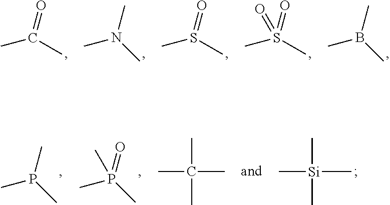

and
the heteroaryl is selected from the group consisting of a monocyclic heteroaryl, and combinations formed by connecting a plurality of heteroaryls or connecting an aryl and a heteroaryl, via any one or more of single bond, —C—C—, —C═C—, —C═N—, —C═P—, —C≡—,

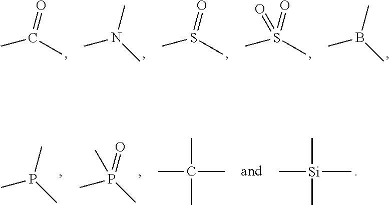

Preferably, the aryl is selected from one or more of phenyl, naphthyl, anthryl, binaphthyl, phenanthryl, dihydrophenanthryl, pyrenyl, perylenyl, tetracenyl, pentacenyl, benzoperylenyl, benzocylopentadienyl, spirobifluorenyl and fluorenyl; and
the heteroaryl is selected from one or more of pyrrolyl, imidazolyl, thienyl, furyl, 1,2-thiazolyl, 1,3-thiazolyl, 1,2,3-oxadiazolyl, 1,2,4-oxadiazolyl, thiadiazolyl, selenadiazolyl, 1,2,3-triazolyl, 1,2,4-triazolyl, pyridyl, pyrazinyl, pyrimidinyl, 1,3,5-triazinyl, 1,2,4-triazinyl, 1,2,3-triazinyl, indolyl, isoindolyl, benzimidazolyl, naphthoimidazolyl, phenanthroimidazolyl, benzotriazolyl, purinyl, benzoxazolyl, naphthoxazolyl, phenanthroxazolyl, benzothiadiazolyl, benzoselenadiazolyl, benzotriazolyl, quinolyl, isoquinolyl, benzopyrazinyl, benzothienyl, benzofuranyl, benzopyrrolyl, carbazolyl, acridinyl, dibenzothienyl, dibenzofuranyl, silafluorenyl, dibenzothienyl-5,5-dioxy, naphthothiadiazolyl, naphthoselenadiazolyl, and 10,15-dihydro-5H-diindolo[3,2-a:3′,2′-c]carbazolyl.

Preferably, Ar has a structure represented by one of Formula (a-1) to Formula (a-8):

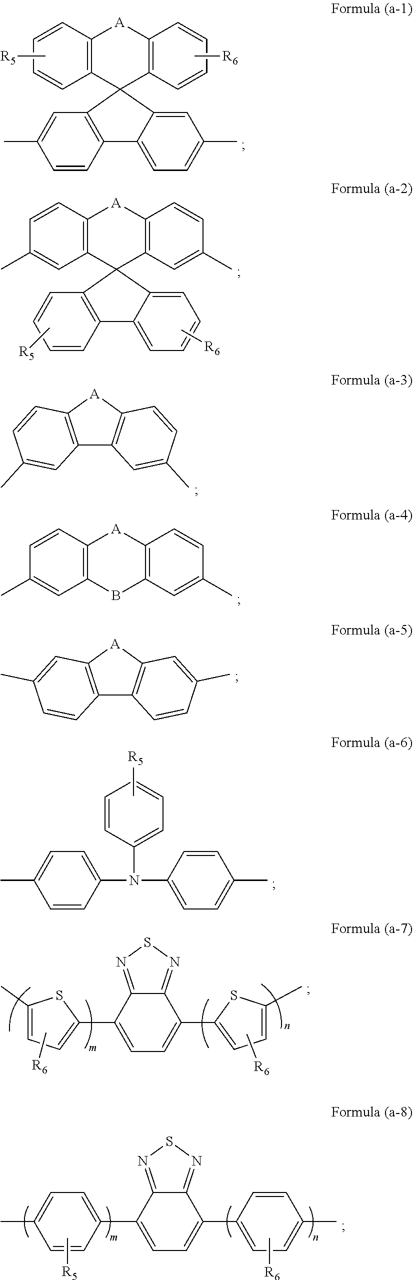

wherein A and B are independently selected from the group consisting of —CR₇R₈—, —NR₉—, —SiR₇R₈, —BR₁₀—, —O—, —S—, —SO—, —SO₂—, —PPhO— and —CO—;
wherein R₅, R₆, R₇, R₈, R₉, and R₁₀ are independently selected from the group consisting of hydrogen, a C1˜C40 alkyl, a C1˜C40 alkoxy, and a C1˜C40 heteroalkyl containing a heteroatom of O, N, S or Si; and
m and n are independently selected from the group consisting of 0, 1 and 2.

Preferably, Ar has a structure represented by Formula (a-5-1), Formula (a-3-1), Formula (a-8-1), Formula (a-4-1), Formula (a-1-1), Formula (a-2-1), Formula (a-7-1), Formula (a-1-2) or Formula (a-2-2):

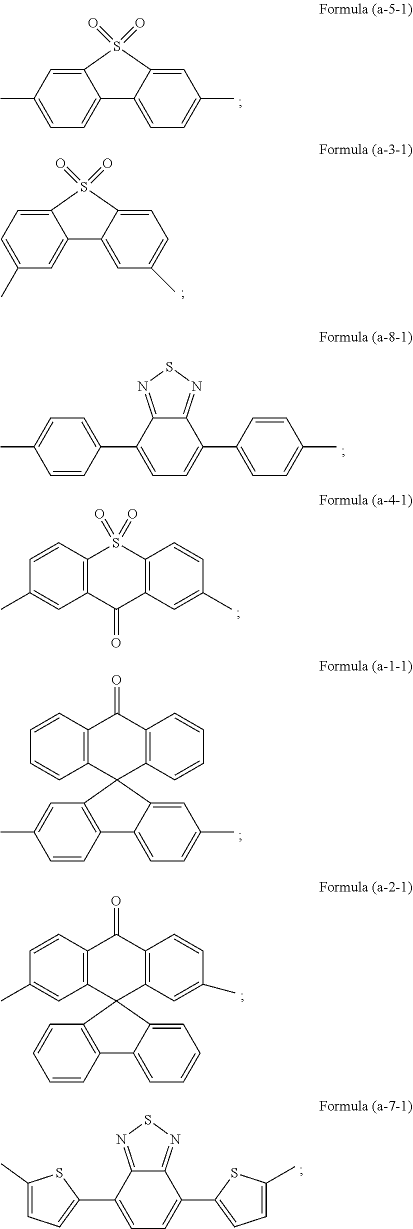

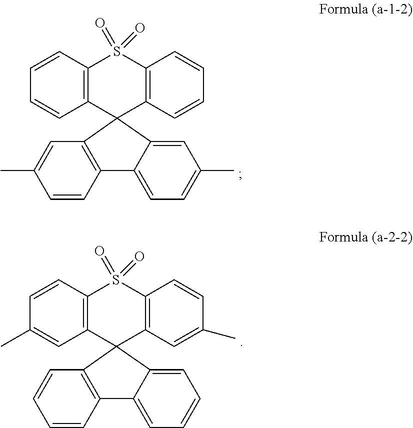

Preferably, the poly(spirobifluorene) has a structure represented by one of Formula (I-1) to Formula (I-7):

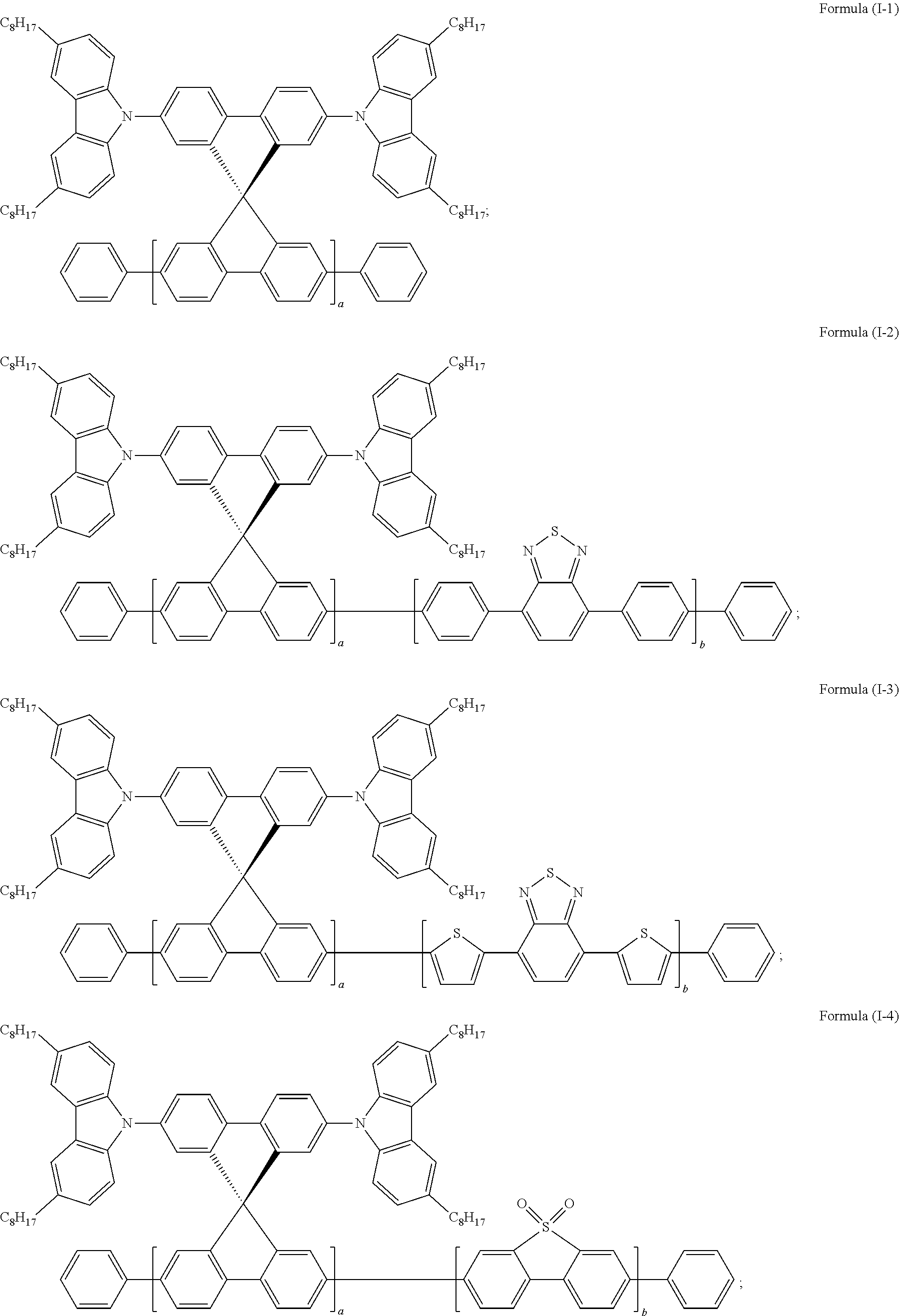

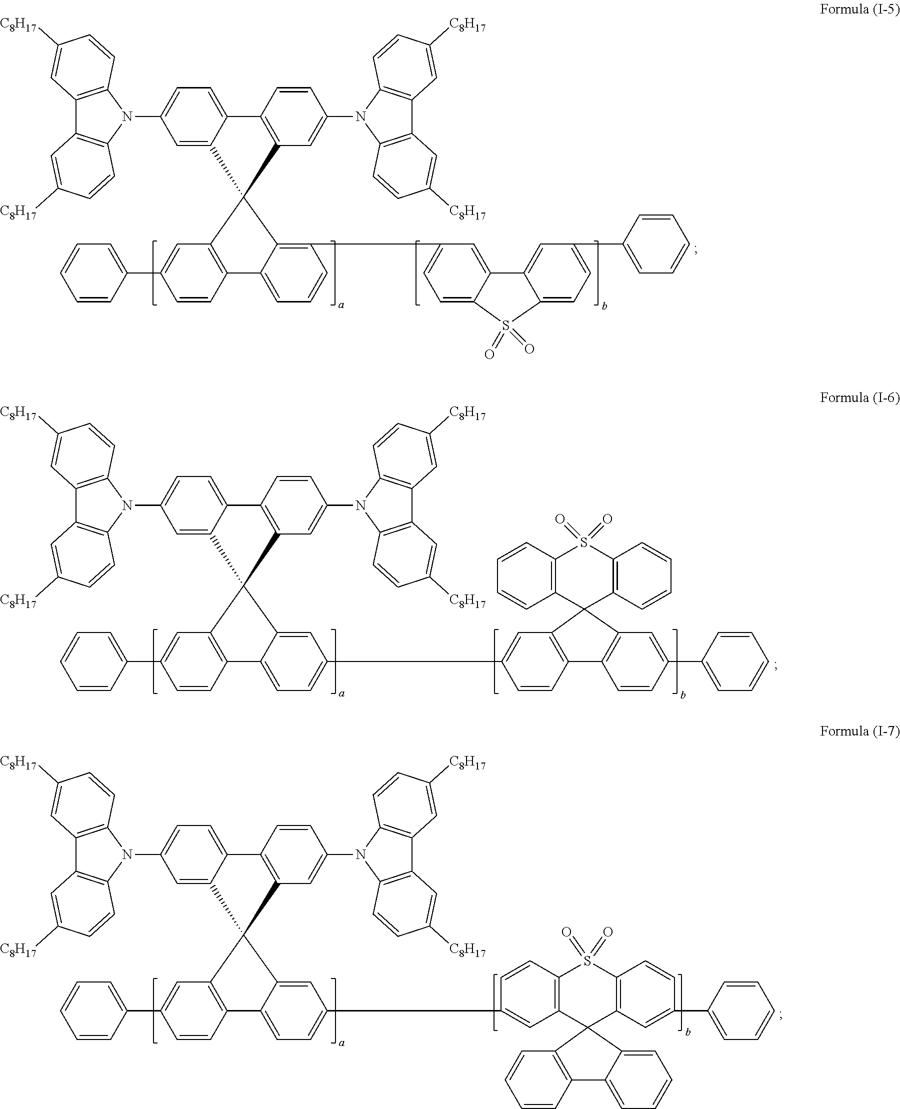

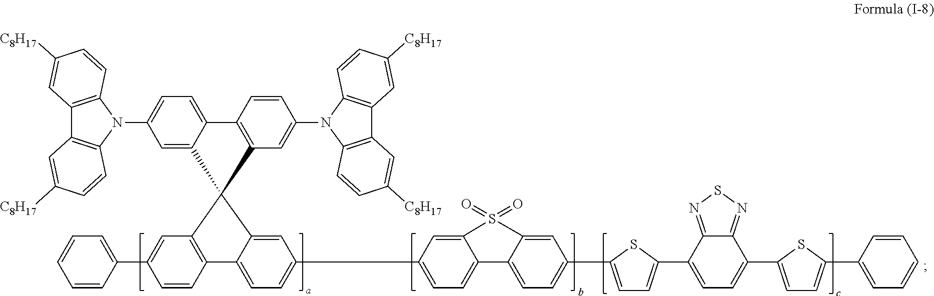

wherein 0.5<a/(a+b+c)≤1.

The present disclosure provides an electroluminescent device comprising a light emitting layer, wherein the light emitting layer is the poly(spirobifluorene) according to any one of the above technical solutions.

As compared to prior art, the present disclosure provides a poly(spirobifluorene) comprising more than 50% proportion of a repeating unit represented by Formula (I): in the present disclosure, a polymer containing carbazolyl spirobifluorene is synthesized by introducing a carbazolyl group at a side chain of a spirobifluorene. No intramolecular charge transfer from a main chain to a side chain occurs in the carbazolyl spirobifluorene polymer prepared in the present disclosure. And the polymer has a good hole transport capability due to the modification with carbazole, and a good device efficiency can be achieved while retaining the advantage of the color purity of pure blue light. Meanwhile, by introducing an aromatic group to the poly(spirobifluorene) of the present disclosure, emission of three primary colors of blue, green and red can be obtained, and a good device efficiency can be achieved.

### BRIEF DESCRIPTION OF DRAWINGS

FIG. 1 is a luminescent spectrum of the CzPSF prepared in Example 7 of the present disclosure in different solvents;

FIG. 2 is absorption and emission spectrums of the CzPSF in a film form;

FIG. 3 is absorption and emission spectrums of the CzSPFDPBT05 prepared in Example 8 of the present disclosure in a film form;

FIG. 4 is absorption and emission spectrums of the CzSPFDPBT05 prepared in Example 9 of the present disclosure in a film form;

FIG. 5 is absorption and emission spectrums of the CzSPF-3,7SO15 prepared in Example 10 of the present disclosure in a film form;

FIG. 6 is absorption and emission spectrums of the CzSPF-2,8SO05 prepared in Example 11 of the present disclosure in a film form;

FIG. 7 is absorption and emission spectrums of the CzSPF-2,7SSO05 prepared in Example 12 of the present disclosure in a film form;

FIG. 8 is absorption and emission spectrums of the CzPSF-2′,7′SSO05 prepared in Example 13 of the present disclosure in a film form;

FIG. 9 is absorption and emission spectrums of the CzPSF-3,7SO15-DTBT05 prepared in Example 14 of the present disclosure in a film form;

FIG. 10 is a luminescent spectrum of the ROPSF prepared in Comparative Example 1 of the present disclosure in different solvents;

FIG. 11 an absorption and emission spectrums of the ROPSF prepared in Comparative Example 1 in a film form; and

FIG. 12 is absorption and emission spectrums of the ROPSF-3,7SO05 prepared in Comparative Example 2 in a film form.

### DETAILED DESCRIPTION

The present disclosure provides a poly(spirobifluorene) comprising more than 50% proportion of a repeating unit represented by Formula (I):

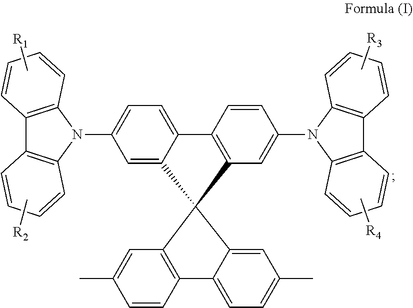

wherein R₁, R₂, R₃ and R₄ are independently selected from the group consisting of a C1˜C22 alkyl, a C1˜C22 alkoxy and a C1˜C22 heteroalkyl.

Preferably, the R₁, R₂, R₃ and R₄ are independently selected from the group consisting of a substituted C1˜C22 linear alkyl, an unsubstituted C1˜C22 linear alkyl, a substituted C1˜C22 branched alkyl, an unsubstituted C1˜C22 branched alkyl, a substituted C3˜C22 cycloalkyl, an unsubstituted C3˜C22 cycloalkyl, a substituted C3˜C22 cycloalkyl, an unsubstituted C1˜C22 alkoxy, a substituted C1˜C22 heteroalkyl, and an unsubstituted C1˜C22 heteroalkyl, wherein the heteroalkyl contains a heteroatom of O, N, S or Si.

More preferably, the R₁, R₂, R₃ and R₄ are independently selected from the group consisting of a substituted C3˜C15 linear alkyl, an unsubstituted C3˜C15 linear alkyl, a substituted C3˜C15 branched alkyl, an unsubstituted C3˜C15 branched alkyl, a substituted C3˜C15 cycloalkyl, an unsubstituted C3˜C15 cycloalkyl, a substituted C3˜C15 cycloalkyl, an unsubstituted C3˜C15 alkoxy, a substituted C3˜C15 heteroalkyl, and an unsubstituted C3˜C15 heteroalkyl, wherein the heteroalkyl contains a heteroatom of O, N, S or Si.

Even more preferably, the R₁, R₂, R₃ and R₄ are independently selected from the group consisting of a substituted C5˜C10 linear alkyl, an unsubstituted C5˜C10 linear alkyl, a substituted C5˜C10 branched alkyl, an unsubstituted C5˜C10 branched alkyl, a substituted C5˜C12 cycloalkyl, an unsubstituted C5˜C12 cycloalkyl, a substituted C5˜C12 cycloalkyl, an unsubstituted C5˜C10 alkoxy, a substituted C5˜C10 heteroalkyl, and an unsubstituted C5˜C10 heteroalkyl, wherein the heteroalkyl contains a heteroatom of O, N, S or Si.

Most preferably, the R₁, R₂, R₃ and R₄ are independently selected from the group consisting of a substituted C5˜C8 linear alkyl, an unsubstituted C5˜C8 linear alkyl, a substituted C5˜C8 branched alkyl, an unsubstituted C5˜C8 branched alkyl, a substituted C5˜C12 cycloalkyl, an unsubstituted C5˜C12 cycloalkyl, a substituted C5˜C12 cycloalkyl, an unsubstituted C5˜C8 alkoxy, a substituted C5˜C8 heteroalkyl, and an unsubstituted C5˜C8 heteroalkyl, wherein the heteroalkyl contains a heteroatom of O, N, S or Si.

In addition, it should be noted that —R₁, —R₂, —R₃ and —R₄ indicate that substituents may be at any site of the aromatic ring on which the substituents are present.

In the present disclosure, the substituted linear alkyl is preferably a linear alkyl substituted with at least one substituent; the substituted branched alkyl is preferably a branched alkyl substituted with at least one substituent; the substituted cycloalkyl is preferably a cycloalkyl substituted with at least one substituent; the substituted alkoxy is preferably an alkoxy substituted with at least one substituent; and the substituted heteroalkyl is preferably a heteroalkyl substituted with at least one substituent; wherein the number of the substituent on the substituted linear alkyl, the substituted branched alkyl, the substituted cycloalkyl, the substituted alkoxy and the substituted heteroalkyl is preferably 1 to 5, and more preferably 2, 3 or 4.

In the present disclosure, the alkyl, the alkoxy, and the heteroalkyl may be optionally substituted with a substituent preferably independently selected from the group consisting of —OH, —SH, —SiH₃, —SiH₂Rₐ, —SiHRₐR_{b}, —SiRₐR_{b}R_{c}, R_{d}NH—, R_{d}RₑN—, NH₂—, a C1˜C15 alkylsulfanyl, —CO—OR_{f} and halogen; wherein the heteroalkyl contains a heteroatom of O, N, S or Si;

The Rₐ, R_{b}, R_{c}, R_{d}, Rₑ and R_{f} are preferably independently selected from the group consisting of a substituted C1˜C22 linear alkyl, an unsubstituted C1˜C22 linear alkyl, a substituted C1˜C22 branched alkyl, an unsubstituted C1˜C22 branched alkyl, a substituted C3˜C22 cycloalkyl, an unsubstituted C3˜C22 cycloalkyl, a substituted C3˜C22 cycloalkyl, an unsubstituted C1˜C22 alkoxy, a substituted C1˜C22 heteroalkyl, and an unsubstituted C1˜C22 heteroalkyl, wherein the heteroalkyl contains a heteroatom of O, N, S or Si.

The poly(spirobifluorene) of the present disclosure preferably comprises only a repeating unit represented by Formula (I).

Preferably, the poly(spirobifluorene) of the present disclosure further comprises a repeating unit represented by Formula (II):

—Ar— Formula (II);
wherein Ar is selected from one or more of a C6˜C60 aryl and a C6˜C60 heteroaryl.

The poly(spirobifluorene) of the present disclosure preferably comprises a repeating unit represented by Formula (I) and a repeating unit represented by Formula (II), and the proportion of the repeating unit represented by Formula (I) is preferably more than 50%, and more preferably more than 60%.

The above repeating units may be connected with each other by homopolymerization or copolymerization, which is not limited in the present disclosure. The groups may be the same or different between the repeating units.

The polymer of the present disclosure may have the following structure:

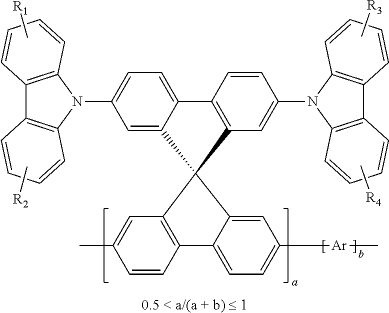

In the present disclosure, the aryl and the heteroaryl may be optionally substituted with a substituent preferably selected from the group consisting of H, halogen, —OH, —SH, —CN, —NO₂, a C1˜C15 alkylsulfanyl, a C1˜C40 alkyl and a C1˜C40 substituted alkyl; wherein the heteroaryl contains a heteroatom independently selected from the group consisting of Si, Ge, N, P, O, S and Se.

In particular, the Ar is an unsubstituted C6˜C60 aryl, a substituted C6˜C60 aryl, an unsubstituted C6˜C60 heteroaryl, or a substituted C6˜C60 heteroaryl; the Ar is preferably an unsubstituted C6˜C50 aryl, a substituted C6˜C50 aryl, an unsubstituted C6˜C50 heteroaryl, or a substituted C6-C50 heteroaryl, wherein the heteroaryl contains a heteroatom independently selected from the group consisting of Si, Ge, N, P, O, S and Se; the Ar is more preferably an unsubstituted C10˜C40 aryl, a substituted C10˜C40 aryl, an unsubstituted C10˜C40 heteroaryl, or a substituted C10˜C40 heteroaryl, wherein the heteroaryl contains a heteroatom independently selected from the group consisting of Si, Ge, N, P, O, S and Se; the Ar is even more preferably an unsubstituted C12˜C30 aryl, a substituted C12˜C30 aryl, an unsubstituted C12˜C30 heteroaryl or a substituted C12˜C30 heteroaryl, wherein the heteroaryl contains a heteroatom independently selected from the group consisting of Si, Ge, N, P, O, S and Se; the Ar is most preferably an unsubstituted C12˜C26 aryl, a substituted C12˜C26 aryl, an unsubstituted C12˜C26 heteroaryl or a substituted C12˜C26 heteroaryl, wherein the heteroaryl contains a heteroatom independently selected from the group consisting of N, P, O and S.

In the present disclosure, the aryl is preferably selected from the group consisting of a monocyclic aryl, and a combination formed by connecting a plurality of aryls via any one or more of single bond, —C—C—, —C═C—, —C═N—, —C═P—, —C≡C—,

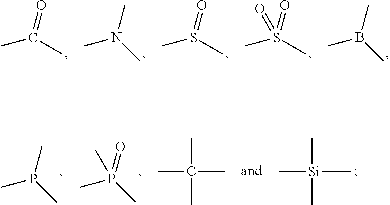

more preferably, the aryl is selected from one or more of phenyl, naphthyl, anthryl, binaphthyl, phenanthryl, dihydrophenanthryl, pyrenyl, perylenyl, tetracenyl, pentacenyl, benzoperylenyl, benzocylopentadienyl, spirobifluorenyl and fluorenyl; and most preferably, the aryl is selected from one or more of phenyl, naphthyl, anthryl, phenanthryl, dihydrophenanthryl, tetracenyl, pentacenyl, benzoperylenyl, benzocylopentadienyl, spirobifluorenyl and fluorenyl.

The heteroaryl is preferably selected from the group consisting of a monocyclic heteroaryl, and a combination formed by connecting a plurality of heteroaryls or by connecting an aryl and a heteroaryl, via any one or more of single bond, —C—C—, —C═C—, —C═N—, —C═P—, —C≡—,

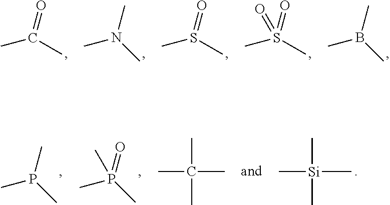

More preferably, the heteroaryl is selected from one or more of pyrrolyl, imidazolyl, thienyl, furyl, 1,2-thiazolyl, 1,3-thiazolyl, 1,2,3-oxadiazolyl, 1,2,4-oxadiazolyl, thiadiazolyl, selenadiazolyl, 1,2,3-triazolyl, 1,2,4-triazolyl, pyridyl, pyrazinyl, pyrimidinyl, 1,3,5-triazinyl, 1,2,4-triazinyl, 1,2,3-triazinyl, indolyl, isoindolyl, benzimidazolyl, naphthoimidazolyl, phenanthroimidazolyl, benzotriazolyl, purinyl, benzoxazolyl, naphthoxazolyl, phenanthroxazolyl, benzothiadiazolyl, benzoselenadiazolyl, benzotriazolyl, quinolyl, isoquinolyl, benzopyrazinyl, benzothienyl, benzofuranyl, benzopyrrolyl, carbazolyl, acridinyl, dibenzothienyl, dibenzofuranyl, silafluorenyl, dibenzothienyl-5,5-dioxy, naphthothiadiazolyl, naphthoselenadiazolyl, and 10,15-dihydro-5H-diindolo[3,2-a:3′,2′-c]carbazolyl. Most preferably, the heteroaryl is selected from one or more of pyrrolyl, imidazolyl, thienyl, furyl, 1,2-thiazolyl, 1,3-thiazolyl, 1,2,3-oxadiazolyl, 1,2,4-oxadiazolyl, thiadiazolyl, selenadiazolyl, 1,2,3-triazolyl, 1,2,4-triazolyl, pyridyl, pyrazinyl, pyrimidinyl, 1,3,5-triazinyl, 1,2,4-triazinyl, 1,2,3-triazinyl, indolyl, isoindolyl, benzimidazolyl, naphthoimidazolyl, phenanthroimidazolyl, benzotriazolyl, purinyl, benzoxazolyl, naphthoxazolyl, phenanthroxazolyl, benzothiadiazolyl, benzotriazolyl, quinolyl, isoquinolyl, benzopyrazinyl, benzothienyl, benzofuranyl, benzopyrrolyl, carbazolyl, acridinyl, dibenzothienyl, dibenzofuranyl, dibenzothienyl-5,5-dioxy, naphthothiadiazolyl, naphthoselenadiazolyl, and 10,15-dihydro-5H-diindolo[3,2-a:3′,2′-c]carbazolyl.

In the present disclosure, the Ar preferably has a structure represented by one of Formula (a-1) to Formula (a-8):

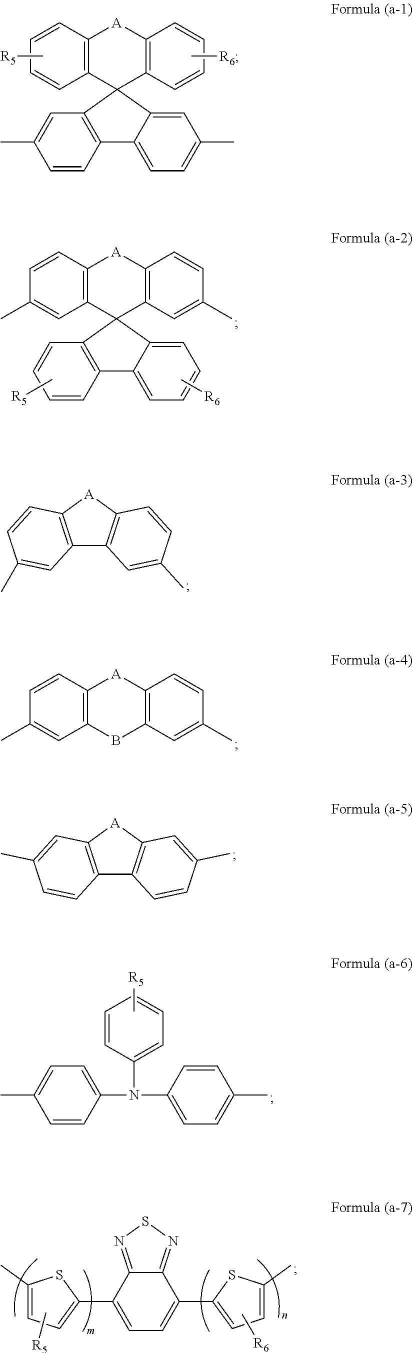

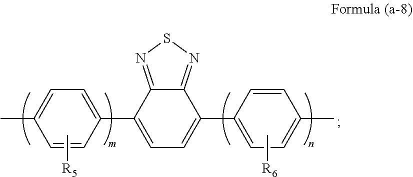

wherein A is independently selected from the group consisting of —CR₇R₈—, —NR₉—, —SiR₇R₈, —BR₁₀—, —O—, —S—, —SO—, —SO₂—, —PPhO— and —CO—;
R₅, R₆, R₇, R₈, R₉ and R₁₀ are independently selected from the group consisting of hydrogen, an unsubstituted C1˜C40 linear alkyl, a substituted C1˜C40 linear alkyl, an unsubstituted C1˜C40 branched alkyl, a substituted C1˜C40 branched alkyl, an unsubstituted C3˜C40 cycloalkyl, a substituted C3˜C40 cycloalkyl, an unsubstituted C1˜C40 alkoxy, a substituted C1˜C40 alkoxy, a substituted C1˜C40 heteroalkyl, and an unsubstituted C1˜C40 heteroalkyl, wherein the heteroalkyl contains a heteroatom of O, N, S or Si;
m and n are independently selected from the group consisting of 0, 1 and 2.

In addition, it should be noted that —R₅ and —R₆ indicate that substituents may be at any site of the aromatic ring on which the substituents are present.

In the present disclosure, Ar more preferably has a structure represented by Formula (a-5-1), Formula (a-3-1), Formula (a-8-1), Formula (a-4-1), Formula (a-1-1), Formula (a-2-1), Formula (a-7-1), Formula (a-1-2) or Formula (a-2-2):

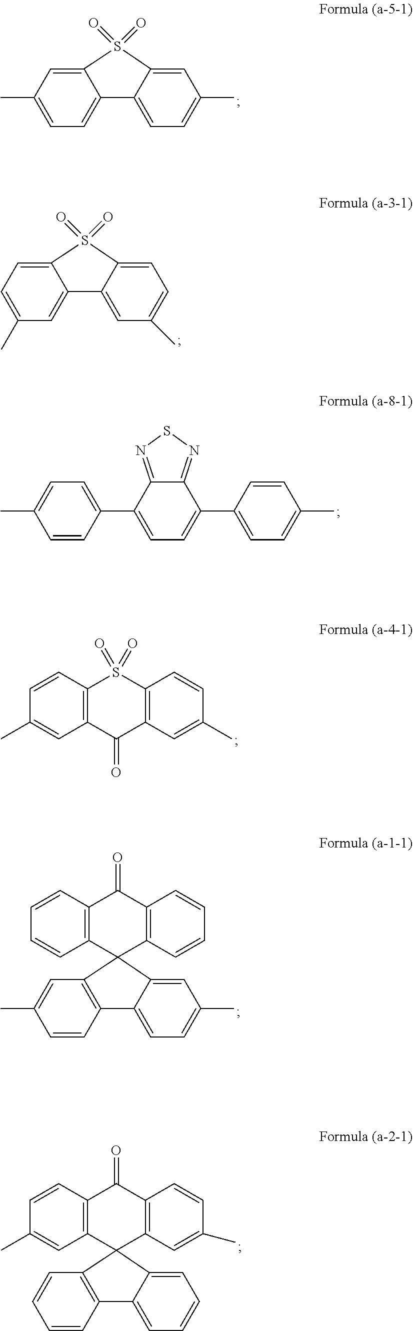

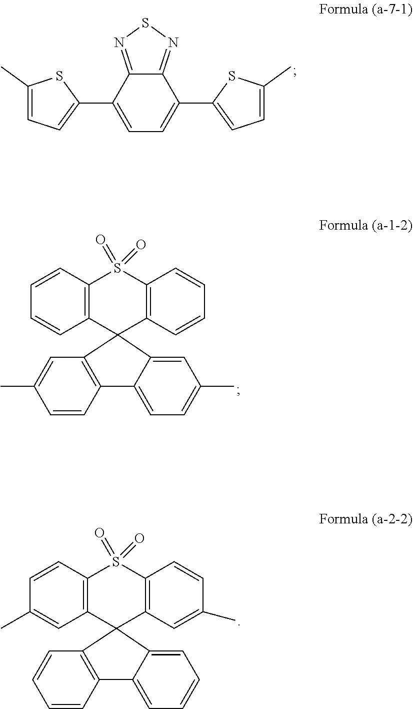

In the present disclosure, the substituted aryl is preferably an aryl substituted with at least one substituent, and the substituted heteroaryl is preferably a heteroaryl substituted with at least one substituent, wherein the substituent of the substituted aryl is selected from the group consisting of H, halogen, —OH, —SH, —CN, —NO₂, a C1˜C15 alkylsulfanyl, a C1˜C40 alkyl, and a C1˜C40 substituted alkyl, and the substituent of the substituted heteroaryl is selected from the group consisting of H, halogen, —OH, —SH, —CN, —NO₂, a C1˜C15 alkylsulfanyl, a C1˜C40 alkyl, and a C1˜C40 substituted alkyl. The number of the substituent on the aryl is preferably 1 to 5, and more preferably 2, 3 or 4.

It should be noted that, in the present disclosure, Ar may be commercially available, or prepared by a conventional method disclosed in prior art.

In the present disclosure, the poly(spirobifluorene) preferably has the following structures.

When R₁, R₂, R₃ and R₄ are C₈H₁₇, b=0, and a=1, the polymer has a structure represented by Formula (I-1), named CzPSF;

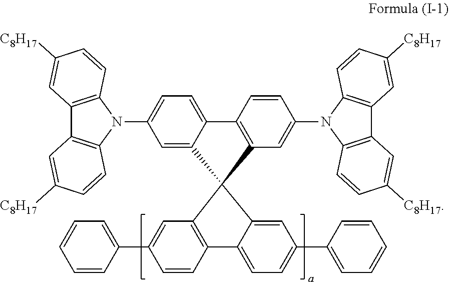

When R₁, R₂, R₃ and R₄ are C₈H₁₇, and Ar is

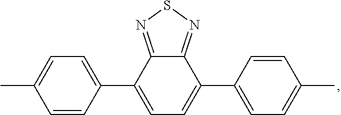

the polymer has a structure represented by Formula (I-2): when b=0.05 and a=0.95, it is named CzPSFDPBT05; when b=0.1 and a=0.9, it is named CzPSFDPBT10; when b=0.15 and a=0.85, it is named CzPSFDPBT15; when b=0.20 and a=0.80, it is named CzPSFDPBT20; and
when b=0.30 and a=0.70, it is named CzPSFDPBT30;

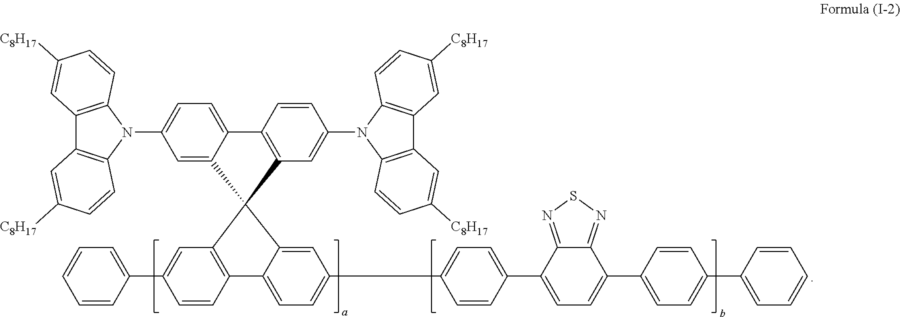

When R₁, R₂, R₃ and R₄ are C₈H₁₇, and Ar is

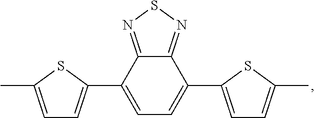

the polymer has a structure represented by Formula (I-3): when b=0.01 and a=0.99, it is named CzPSFDTBT01; when b=0.03 and a=0.97, it is named CzPSFDTBT03; when b=0.05 and a=0.95, it is named CzPSFDTBT05; when b=0.07 and a=0.93, it is named CzPSFDTBT07; and when b=0.1 and a=0.90, it is named CzPSFDTBT10;

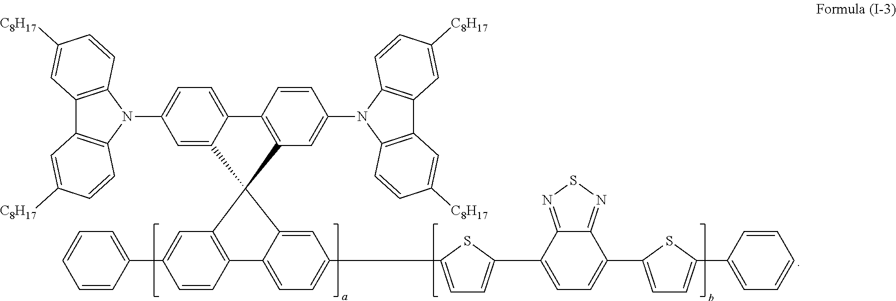

When R₁, R₂, R₃ and R₄ are C8H₁₇, and Ar is

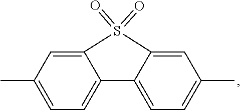

the polymer has a structure represented by Formula (I-4): when b=0.05 and a=0.95, it is named CzPSF-3,7SO05; when b=0.10 and a=0.90, it is named CzPSF-3,7SO10;
when b=0.15 and a=0.85, it is named CzPSF-3,7SO15; when b=0.20 and a=0.80, it is named CzPSF-3,7SO20; and when b=0.30 and a=0.70, it is named CzPSF-3,7SO30;

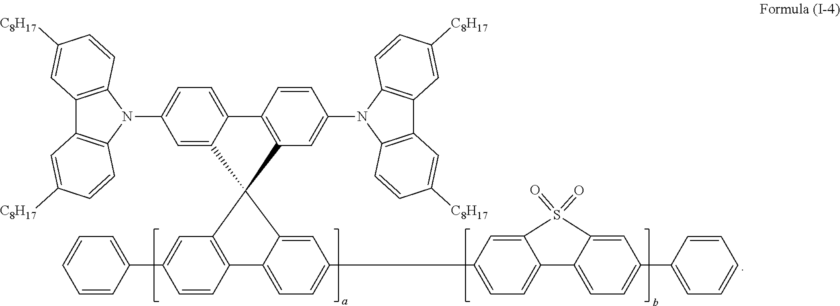

When R₁, R₂, R₃ and R₄ are C₈H₁₇, and Ar is

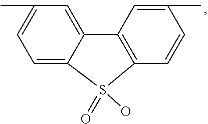

the polymer has a structure represented by Formula (I-5): when b=0.05 and a=0.95, it is named CzPSF-2,8SO05; when b=0.10 and a=0.90, it is named CzPSF-2,8SO10;
when b=0.15 and a=0.85, it is named CzPSF-2,8SO15; when b=0.20 and a=0.80, it is named CzPSF-2,8SO20; and when b=0.30 and a=0.70, it is named CzPSF-2,8SO30;

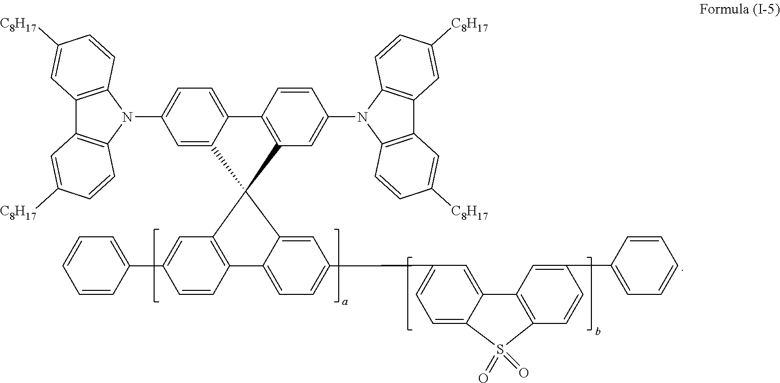

When R₁, R₂, R₃ and R₄ are C₈H₁₇, and Ar is

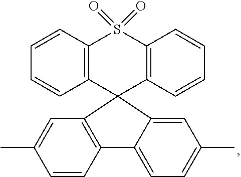

the polymer has a structure represented by Formula (I-6):
when b=0.05 and a=0.95, it is named CzPSF-2,7SSO05; when b=0.10 and a=0.90, it is named CzPSF-2,7SSO10; when b=0.15 and a=0.85, it is named CzPSF-2,7SSO15; when b=0.20 and a=0.80, it is named CzPSF-2,7SSO20; when b=0.30 and a=0.70, it is named CzPSF-2,7SSO30; and when b=0.50 and a=0.50, it is named CzPSF-2,7SSO50;

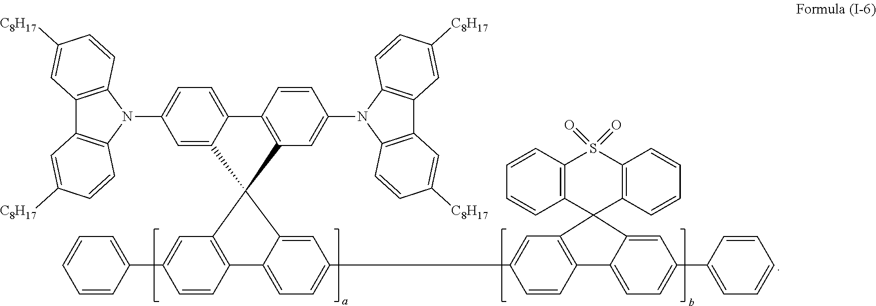

When R₁, R₂, R₃ and R₄ are C₈H₁₇, and Ar is

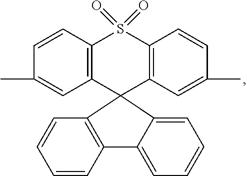

the polymer has a structure represented by Formula (I-7): when b=0.05 and a=0.95, it is named CzPSF-2′,7′SSO05; when b=0.10 and a=0.90, it is named CzPSF-2′,7′SSO10; when b=0.15 and a=0.85, it is named CzPSF-2′,7′SSO15; when b=0.20 and a=0.80, it is named CzPSF-2′,7′SSO20; when b=0.30 and a=0.70, it is named CzPSF-2′,7′SSO30; and when b=0.50 and a=0.50, it is named CzPSF-2′,7′SSO50;

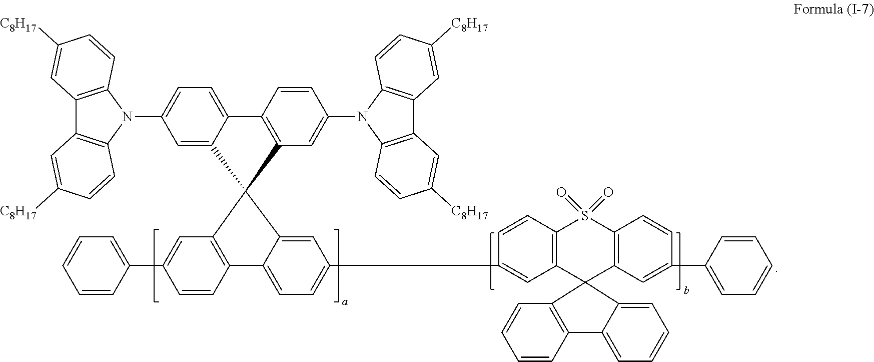

When R₁, R₂, R₃ and R₄ are C₈H₁₇, and Ar is a combination of

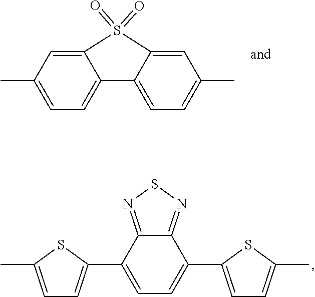

the polymer has a structure represented by Formula (I-8): when c=0.01, b=0.15 and a=0.84, it is named CzPSF-3,7SO15-DTBT01; when c=0.03, b=0.15 and a=0.82, it is named CzPSF-3,7SO15-DTBT03; when c=0.05, b=0.15 and a=0.80, it is named CzPSF-3,7SO15-DTBT05; when c=0.07, b=0.15 and a=0.78, it is named CzPSF-3,7SO15-DTBT07; when c=0.10, b=0.10 and a=0.80, it is named CzPSF-3,7SO15-DTBT010; when c=0.01, b=0.10 and a=0.89, it is named CzPSF-3,7SO10-DTBT01; when c=0.03, b=0.10 and a=0.87, it is named CzPSF-3,7SO10-DTBT03; when c=0.05, b=0.10 and a=0.85, it is named CzPSF-3,7SO10-DTBT05; when c=0.07, b=0.10 and a=0.83, it is named CzPSF-3,7SO10-DTBT07; and when c=0.10, b=0.10 and a=0.80, it is named CzPSF-3,7SO10-DTBT010; wherein 0.5<a/(a+b+c)<1;

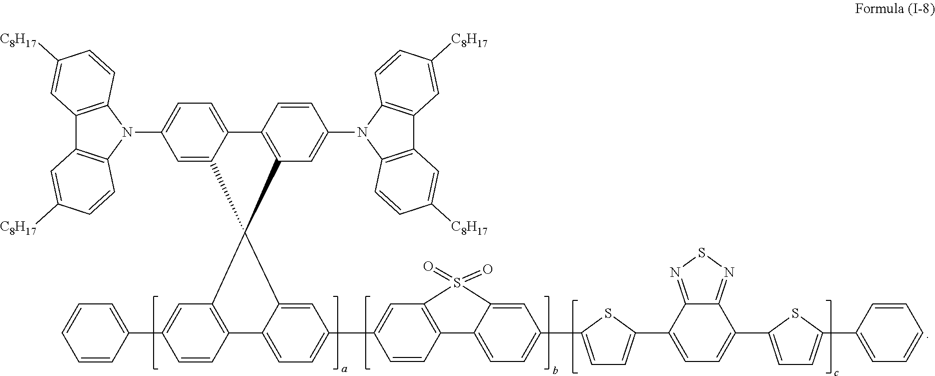

In the present disclosure, the number average molecular weight (Mn) of the poly(spirobifluorene) is preferably 10,000-1,000,000 Da, and the polydispersity index (PDI) is preferably 1.1-4.0.

In the present disclosure, the repeating unit with carbazolyl is a first repeating unit, Ar is a second repeating unit, and the polymerization degree of the poly(spirobifluorene) is preferably such that 5≤n≤1000.

The present disclosure provides a method of preparing a poly(spirobifluorene), comprising:
polymerizing a di-halogen monomer of Formula (II) and a di-boron derivative monomer of Formula (III) in the presence of a palladium compound, an alkaline compound, an organophosphorus compound, a solvent and a catalyst to obtain a poly(spirobifluorene);
or polymerizing a di-halogen monomer of Formula (II), a di-boron derivative monomer of Formula (III) and an aromatic compound in the presence of a palladium compound, an alkaline compound, an organophosphorus compound, a solvent and a catalyst to obtain a poly(spirobifluorene);

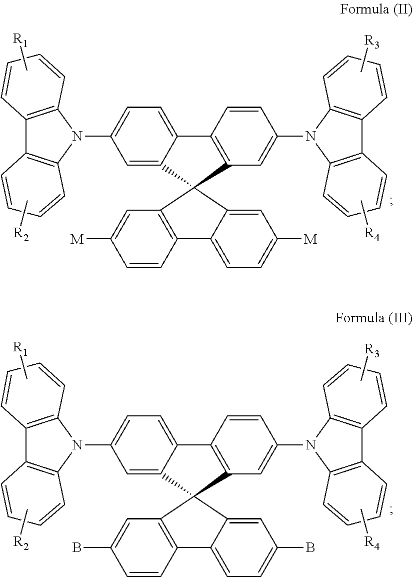

wherein R₁, R₂, R₃ and R₄ are independently selected from the group consisting of a C1˜C22 linear alkyl, a C1˜C22 branched alkyl, a C3˜C22 cycloalkyl, a C1˜C22 alkoxy and a C1˜C22 heteroalkyl;
M is selected from one of trifluoromethanesulfonyl chloride and halogen; and B is selected from the group consisting of a boric acid group, a borate ester group, and a borane group.

In the present disclosure, a di-halogen monomer of Formula (II) and a di-boron derivative monomer of Formula (III) are polymerized in the presence of a palladium compound, an alkaline compound, an organophosphorus compound, a solvent and a catalyst to obtain a poly(spirobifluorene). The molar ratio of the di-halogen monomer of Formula (II) to the di-boron derivative monomer of Formula (III) is preferably (0.5˜1.5):(0.5˜1.5), and more preferably 1:1. The molar ratio of the palladium compound to the di-halogen monomer of Formula (II) is preferably (0.005˜0.01):1. The molar ratio of the alkaline compound to the di-halogen monomer of Formula (II) is preferably (5˜20):1. The molar ratio of the organophosphorus compound to the di-halogen monomer of Formula (II) is preferably 0.01˜0.06:1. The molar ratio of the catalyst to the di-halogen monomer of Formula (II) is preferably 0.04˜0.1:1.

In the present disclosure, the temperature of the polymerization is preferably 85 to 100° C. and more preferably 90 to 100° C. The time of the polymerization is preferably 1 to 24 hrs, and more preferably 1.5 to 2 hrs. The polymerization is a Suzuki polymerization.

After the completion of the reaction, the resultant is preferably poured into an organic solvent, washed, dried, and precipitated to obtain the product. The organic solvent includes, but not limited to dichloromethane. The washing is preferably performed with one or more of sodium chloride and distilled water. The washing is preferably performed once to three times. The drying is preferably performed over anhydrous sodium sulfate. After the drying, a concentration process is preferably performed. In the present disclosure, the concentration process is not limited, as long as it is well known to those skilled in the art. The precipitation is preferably performed with methanol. The precipitate is preferably dried in vacuo to obtain the poly(spirobifluorene).

In the present disclosure, R₁, R₂, R₃ and R₄ have been specifically described above, and will not be reiterated here.

In the present disclosure, M is selected from one of trifluoromethanesulfonyl chloride and halogen, and is preferably halogen, more preferably Cl, Br or I, and most preferably Br. B is selected from the group consisting of a boric acid group, a borate ester group, and a borane group, and is preferably a borate ester group, and more preferably 2-phenyl-1,3-propanediol borate.

In the present disclosure, the palladium compound is preferably palladium acetate, palladium tetrakis(triphenyl)phosphine, or tris(dibenzylideneacetone)dipalladium; the organophosphorus compound is preferably triphenylphosphine, tricyclohexyl phosphine, tri-tert-butylphosphine, 2-dicyclohexylphosphinyl-2,4,6-triisopropylbiphenyl, tri(2-methoxyphenyl)phosphine or 2-dicylcohexylphosphinyl-2′,6′-dimethylbiphenyl; the alkaline compound is preferably sodium carbonate, potassium carbonate, cesium carbonate, or potassium phosphate; the catalyst is preferably a phase transfer catalyst, which is preferably trioctylmethylammonium chloride; and the organic solvent is preferably tetrahydrofuran, toluene or xylene.

In the present disclosure, the di-halogen monomer of Formula (II) is preferably prepared by the following method:

4,4′-di-iodobiphenyl as starting material is subjected to halogenation, subjected to Ullmann coupling reaction with an alkyl-substituted carbazole, and reacted with a ketone-based derivative to produce an alcohol, which is then subjected to a ring-closing reaction.

Biphenyl is halogenated to obtain a halo-biphenyl. The halo-biphenyl is subjected to Ullmann coupling reaction with an alkyl-substituted carbazole to obtain a first intermediate. The halo-biphenyl includes, but not limited to 2-bromo-4,4-diiodo-biphenyl. The alkyl-substituted carbazole is preferably a C2˜C20 alkyl-substituted carbazole, and more preferably a C5˜C15 alkyl-substituted carbazole. The reaction temperature is preferably 90 to 100° C. The reaction time is preferably 10 to 12 hrs.

The first intermediate is reacted with a ketone-based derivative to produce an alcohol, which is then subjected to a ring-closing reaction to obtain the di-halogen monomer of Formula (II).

The reaction temperature is preferably 25 to 50° C. The reaction time is preferably 5 to 10 hrs.

The second intermediate is subjected to a ring-closing reaction to obtain the di-halogen monomer of Formula (II).

The reaction temperature is preferably 60 to 100° C. The reaction solvent is preferably acetic acid or a mixed solvent of acetic acid and chloroform, acetic acid and tetrahydrofuran, or acetic acid and 1,4-dioxane, in which the mixing volume ratio is preferably greater than 1. The reaction time is preferably 3 to 24 hrs.

In the present disclosure, the di-boron derivative monomer of Formula (III) is preferably prepared by the following method:
the di-halogen monomer of Formula (II) is subjected to a catalytic coupling reaction, or a lithium salt exchange and then esterification.

The catalyst for the catalysis is preferably Pd(OAc)₂, Pd₂(dba)₃ or Pd(PPh₃)₄. The reaction temperature is preferably 50 to 100° C. The reaction time is preferably 1 to 10 hrs. The lithium salt is preferably n-butyl lithium.

The alcohol required for the esterification is preferably pinacol, 1,3-propanediol or 2-phenyl-1,3-propanediol. The reaction is carried out preferably at a temperature of −80° C. to −70° C. for 0.5 to 1.5 hrs, and warmed to room temperature for 10 to 12 hrs.

After the completion of the reaction, the resultant is preferably supplemented with an acid solution, stirred, extracted, dried, purified by column chromatography, and recrystallized.

The acid solution is preferably hydrochloric acid, sulfuric acid or nitric acid. The concentration of the acid solution is preferably 2 to 4 mon. The stirring time is preferably 4 to 6 hrs. The extraction is preferably performed with dichloroalkane. The drying is preferably performed over anhydrous sodium sulfate or anhydrous potassium sulfate. The column chromatography is preferably performed with silica gel as stationary phase. Dichloroalkane and petroleum ether are used as eluent.

The poly(spirobifluorene) of the present disclosure may also be prepared by the following method:
polymerizing a di-halogen monomer of Formula (II), a di-boron derivative monomer of Formula (III) and an aromatic compound in the presence of a palladium compound, an alkaline compound, an organophosphorus compound, a solvent and a catalyst to obtain the poly(spirobifluorene).

In the present disclosure, the aromatic compound preferably has a structure represented by one of Formula (a-1) to Formula (a-8). The mass ratio of the aromatic compound to the sum of the di-halogen monomer and the di-boron derivative monomer is preferably (1˜50):(50˜99).

The remaining steps of the method have been described in detail above, and will not be reiterated here.

The source of the aromatic compound is not limited in the present disclosure. The aromatic compound may be commercially available, or prepared by a method disclosed in prior art, in particular, preferably the following methods:

M-1:

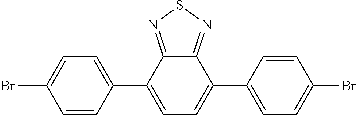 [SMILES: Brc1ccc(-c2ccc(-c3ccc(Br)cc3)c3nsnc23)cc1]

is preferably prepared according to the method as disclosed in Tsuchiya (Macromolecules, 2011, 44, 5200-5208); M-2:

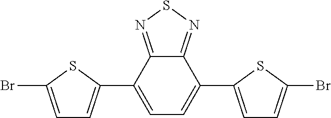 [SMILES: Brc1ccc(-c2ccc(-c3ccc(Br)s3)c3nsnc23)s1]

is preferably prepared according to the method as disclosed in Zhao Xiaoyong (Chemistry of Materials, 2010, 22, 2325-2332); M-3:

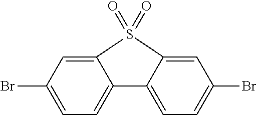 [SMILES: O=S1(=O)c2cc(Br)ccc2-c2ccc(Br)cc21]

is preferably prepared according to the method as disclosed in Wang Chengliang (Crystal Growth and Design, 2010, 10, 4155-4160); M-4:

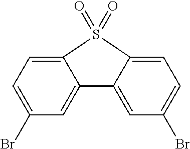 [SMILES: O=S1(=O)c2ccc(Br)cc2-c2cc(Br)ccc21]

is preferably prepared according to the method as disclosed in US2005/171079 A1; M-5:

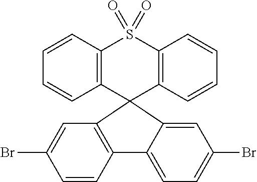 [SMILES: O=S1(=O)c2ccccc2C2(c3cc(Br)ccc3-c3ccc(Br)cc32)c2ccccc21]

is preferably prepared according to the method as disclosed in Chan Chinyiu (Chemistry of Materials, 2014, 26, 6585-6594); and M-6:

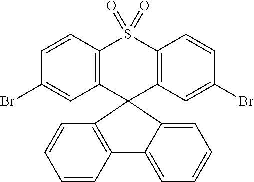 [SMILES: O=S1(=O)c2ccc(Br)cc2C2(c3ccccc3-c3ccccc32)c2cc(Br)ccc21]

is preferably prepared according to the method as disclosed in Li Yunchuan (Chemistry of Materials, 2015, 27, 1100-1109).

The present disclosure further provides an electroluminescent device comprising a light emitting layer, wherein the light emitting layer is the poly(spirobifluorene) according to any one of claims 1 to 9.

In particular, the organic electroluminescent device of the present application preferably comprises:
a substrate, an anode, a cathode, and one or more organic compound layers disposed between the anode and the cathode, wherein only one of the organic compound layers comprises a compound having a structure represented by Formula (I), wherein the compound having a structure represented by Formula (I) may be present in the organic layer in single form or in a mixture with other materials.

The anode, the cathode and the substrate are not limited in the present disclosure, as long as they are well known to those skilled in the art. The substrate is preferably a glass substrate.

In particular, in addition to the light emitting layer, the organic layer comprises one or more of a hole injection layer, a hole transport layer, a layer with both hole injection and hole transport functions, an electron blocking layer, a hole blocking layer, an electron transport layer, an electron injection layer, and a layer with both electron transport and electron injection functions.

At least one of the hole injection layer, the hole transport layer, and the layer with both hole injection and hole transport functions may be a conventional hole injection material, hole transport material, or material with both hole injection and hole transport functions, or a material produced by an electron transport material.

The term “organic compound layer” in the present disclosure is applicable to all the layers disposed between the anode and the cathode of the organic electroluminescent device.

In the present disclosure, when the organic layer comprises a light emitting layer and an electron transport layer, the compound of Formula (I) may be present in one or both of the layers. The electron transport layer is preferably selected from the group consisting of DPSF (2,7-bis(diphenoxyphosphinyl)-9,9′-spirobifluorene), TPBi (1,3,5-tri(1-phenyl-1H-benzimidazol-2-yl)benzene), and TmPyPB (1,3,5-tri[(3-pyridyl)-3-phenyl]benzene), and more preferably DPSF.

The device prepared with the compound having a structure represented by Formula (I) of the present disclosure may be used for organic light emitting diode (OLED), organic solar cell (OSC), electronic paper (e-Paper), organic photoconductor (OPC) or organic thin film transistor (OTFT).

The device of the present disclosure may be manufactured by forming an anode on a substrate through depositing a metal, a conductive oxide, or an alloy thereof via processes such as thin film evaporation deposition, electron beam evaporation, and physical vapor deposition, or via spin-coating or thin strip leading evaporation deposition. The device may also be manufactured with reduced layer number through processes such as tape-casting, doctor-blading, screen-printing, ink jet printing and thermal-imaging.

In the poly(spirobifluorene) system, the modification group of the fluorene in the side chain moiety will change the photophysical properties of the fluorene in the main chain moiety, and thus the modification group in the side chain moiety has an important function of determining the properties of the poly(spirobifluorene).

The inventors have inventively discovered that a polymer containing carbazolyl spirobifluorene is synthesized by introducing a carbazolyl group at a side chain of a spirobifluorene. No intramolecular charge transfer from a main chain to a side chain occurs in the obtained carbazolyl spirobifluorene polymer. And the polymer has a good hole transport capability due to the modification with carbazole, and a good device efficiency can be achieved without any hole transport unit while retaining the advantage of the color purity of pure blue light. Meanwhile, by introducing an aromatic group to the poly(spirobifluorene) of the present disclosure, emission of three primary colors of blue, green and red can be obtained, and a good device efficiency can be achieved.

In order to further illustrate the present disclosure, the poly(spirobifluorene) and a preparation method thereof provided in the present disclosure will be described in detail below with reference to examples.

### Example 1

Carbazole (50 g, 0.3 mol), AlCl₃ (88.0 g, 0.66 mol) and dry dichloromethane (300 mL) were added to a 1 L three necked flask, and mechanically stirred to dissolve. N-octanoyl chloride (115 mL, 0.66 mol) was dropwise added to the reaction system under an argon atmosphere, and a tail gas was passed into a sodium hydroxide solution. After the addition, the mixture was heated to 45° C. to reflux and reacted for 12 hrs. 3M HCl solution (300 mL) was dropwise added to the reaction system, and the dichloromethane solvent was evaporated to obtain a brown solid. The resultant brown solid was washed with a large amount of distilled water to obtain 3,6-di(1-octanoyl)carbazole powder (82.8 g, yield: 65.8%). The purity was 99.0%. A nuclear magnetic resonance analysis was performed on the obtained product, and the result was as follows: ¹H NMR (400 MHz, CDCl₃, 6): 8.79 (d, J=1.1 Hz, 2H), 8.61 (s, 1H), 8.15 (dd, J=8.5, 1.5 Hz, 2H), 7.50 (d, J=8.6 Hz, 2H), 3.11 (t, J=7.5 Hz, 4H), 1.88-1.75 (m, 4H), 1.49-1.25 (m, J=47.7, 8.0 Hz, 16H), 0.90 (t, J=6.9 Hz, 6H).

### Example 2

3,6-Di(1-octanoyl)carbazole powder (57.0 g, 136 mmol) obtained in Example 1, hydrazine hydrate (132 mL, 2.17 mol), sodium hydroxide (54.4 g, 1.36 mol) and diethylene glycol (500 mL) were added to a 1 L three necked flask. The three necks of the flask were equipped with a mechanical stirring device, a built-in thermometer, and a water separator respectively. Under stirring, the mixture was heated to 110° C., and reacted for 4 hrs, heated to 150° C. and reacted for 12 hrs, and heated to 190° C. and reacted for 6 hrs. Gas and water generated were discharged. The mixture was then heated to 210° C. and reacted for 6 hrs. After the completion of the reaction, the system was cooled down to room temperature, poured into a large amount of water, and filtered. The filter cake was dried under suction. The resultant was purified by column chromatography with 200-300 mesh silica gel as stationary phase and dichloromethane as eluent to obtain 3,6-dioctylcarbazole as light yellow solid (43 g, yield: 65%). The purity was 99.0%. Nuclear magnetic resonance analysis: ¹H NMR (400 MHz, CDCl₃ 6): 7.84 (d, J=0.7 Hz, 2H), 7.31 (s, 1H), 7.29 (s, 1H), 7.22 (d, J=1.5 Hz, 1H), 7.20 (d, J=1.5 Hz, 1H), 2.76 (t, 4H), 1.74-1.64 (m, J=15.3, 7.6 Hz, 4H), 1.44-1.20 (m, 20H), 0.88 (t, J=6.8 Hz, 6H).

### Example 3

3,6-dioctylcarbazole (26 g, 66 mmol) obtained in Example 2, 2-bromo-4,4-diiodobiphenyl (15.0 g, 30 mmol), anhydrous potassium phosphate (26.4 g, 120 mmol), (S,S) trans-1,2-cyclohexanediamine (0.94 g, 6 mmol) and cuprous iodide (0.61 g, 3 mmol) were added to a three necked flask containing 1,4-dioxane (500 mL). The mixture was stirred, heated to 100° C., and reacted for 12 hrs under an argon atmosphere. The resultant was dissolved in dichloromethane (300 mL), supplemented with NH₄Cl solution (200 mL), and extracted with dichloromethane. The organic phase was dried over anhydrous sodium sulfate, concentrated, and then purified by column chromatography with 200-300 mesh silica gel as stationary phase and dichloromethane as eluent, to obtain a first intermediate of Formula (IV) (24.5 g, yield: 73%). The purity was 95.0%. Nuclear magnetic resonance analysis: ¹H NMR (400 MHz, CDCl₃ 6): 7.96 (s, 1H), 7.93 (d, J=2.9 Hz, 4H), 7.68 (dd, J=20.8, 12.3 Hz, 5H), 7.44 (t, 4H), 7.26 (t, 5H), 2.81 (t, J=7.7 Hz, 8H), 1.79-1.66 (m, 8H), 1.43-1.26 (m, J=23.1, 14.8 Hz, 40H), 0.89 (t, J=6.7 Hz, 12H).

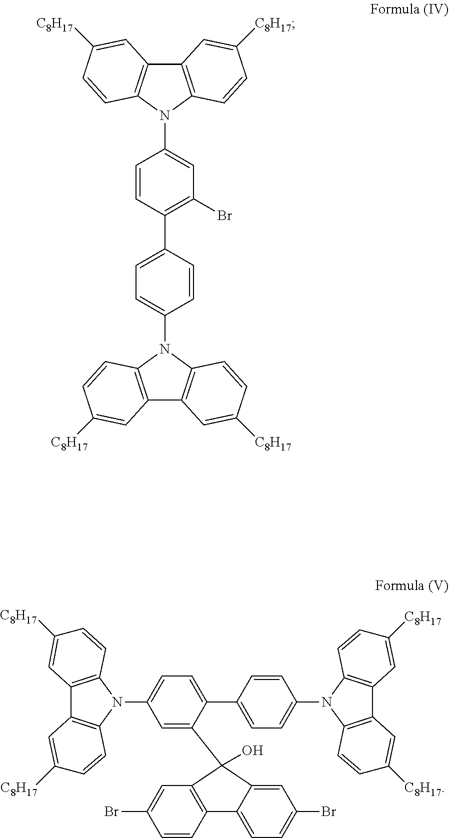

### Example 4

A 1 L three necked flask was baked for three time, and then anhydrous lithium chloride (4.22 g, 102 mmol), magnesium strip (3.72 g, 150 mmol), one grain of elemental iodine, a few amount of bromoethane and 5 mL refined tetrahydrofuran were added thereto under an argon atmosphere. The first intermediate of Formula (IV) prepared in Example 3 was dissolved in 500 mL refined tetrahydrofuran, and then was dropwise added to the reaction system. The mixture was reacted at room temperature under stirring for 5 hrs. The reaction solution was dropwise added to a 1 L reaction flask containing 2,7-dibromofluorenone (34.3 g, 100 mmol), and reacted at room temperature under stirring for 4 hrs. The reaction solution was supplemented with a large amount of water, and extracted with dichloromethane for three times. The organic phase was dried over anhydrous sodium sulfate, concentrated, and then purified by column chromatography with 200-300 mesh silica gel as stationary phase and dichloromethane and petroleum ether as eluent, to obtain a second intermediate of Formula (V) (40 g, yield: 50%). The purity was 98.0%. Nuclear magnetic resonance analysis: 1H NMR (400 MHz, CDCl₃ δ): 8.83 (s, 1H), 8.05 (d, J=24.2 Hz, 4H), 7.73 (dd, J=13.1, 5.1 Hz, 3H), 7.59 (d, J=1.0 Hz, 2H), 7.51 (dd, J=8.0, 1.3 Hz, 2H), 7.47-7.37 (m, 8H), 7.25 (d, J=8.0 Hz, 2H), 7.11 (d, J=8.1 Hz, 2H), 6.53 (d, J=7.8 Hz, 2H), 2.96 (d, J=7.7 Hz, 8H), 1.93-1.79 (m, 8H), 1.59-1.35 (m, 40H), 0.99 (t, J=6.4 Hz, 12H).

### Example 5

The second intermediate of Formula (V) (15.0 g, 11.8 mmol) prepared in Example 4 was dissolved in a mixed solvent of 230 mL glacial acetic acid and 95 mL 1,4-dioxane. The reaction solution was heated to 100° C. under stirring. 10 mL concentrated hydrochloric acid was slowly added to the reaction system. The reaction system was reacted for 2 hrs, supplemented with a large amount of water, and extracted with dichloromethane. The organic phase was dried over anhydrous sodium sulfate, concentrated, and then purified by column chromatography with 200-300 mesh silica gel as stationary phase and dichloromethane and petroleum ether as eluent. The resultant was concentrated and precipitated in methanol to obtain a carbazolyl spirobifluorene dibromide monomer (14.0 g, yield: 94.7%). The purity was 99.0%. Nuclear magnetic resonance analysis: 1H NMR (400 MHz, CDCl₃ δ): 8.08 (d, J=8.1 Hz, 2H), 7.84 (s, 4H), 7.66 (dd, J=8.1, 1.9 Hz, 2H), 7.58 (d, J=8.2 Hz, 2H), 7.49 (dd, J=8.2, 1.8 Hz, 2H), 7.16 (t, 8H), 7.09 (d, J=1.7 Hz, 2H), 6.95 (d, J=1.8 Hz, 2H), 2.74 (t, 8H), 1.74-1.58 (m, 8H), 1.40-1.14 (m, 40H), 0.87 (t, J=6.8 Hz, 12H).

### Example 6

Under an argon atmosphere, the carbazolyl spirobifluorene dibromide monomer (30.0 g, 23.9 mmol) prepared in Example 5 was dissolved in 600 mL refined tetrahydrofuran, and placed in a dry ice-acetone bath for 0.5 hr. n-butyl lithium (27.3 mL, 66.9 mmol) was dropwise added to the reaction system, and stirred for 1 hr. Then, trimethyl borate (1.0 mL, 86.04 mmol) was dropwise added to the reaction solution, and reacted at −78° C. for 1 hr. The reaction system was naturally warmed up to room temperature, and reacted for 12 hrs. The reaction system was supplemented with 300 mL of 3M hydrochloric acid solution, stirred for 5 hrs, extracted with dichloromethane for three times, and dried over anhydrous sodium sulfate. The organic phase was removed to obtain a light yellow foam-like solid. The light yellow solid and 2-phenyl-1,3-propanediol (12.0 g, 78.8 mmol) were dissolved in 200 mL dry dichloromethane, stirred at room temperature for 5 hrs, concentrated, and then purified by column chromatography with 200-300 mesh silica gel as stationary phase and dichloromethane and petroleum ether as eluent. The resultant solid was recrystallized to obtain a carbazolyl spirobifluorene di-borate ester monomer as white lamellar crystal (19.0 g, yield: 55%). The purity was 99.0%. Nuclear magnetic resonance analysis: 1H NMR (400 MHz, CDCl₃, δ): 8.09 (d, J=8.1 Hz, 2H), 7.89-7.79 (m, 8H), 7.64 (dd, J=8.1, 1.9 Hz, 2H), 7.41 (s, 2H), 7.38-7.28 (m, 8H), 7.25-7.18 (m, J=7.6, 4.9 Hz, 8H), 7.15 (dd, J=8.4, 1.5 Hz, 4H), 6.98 (d, J=1.8 Hz, 2H), 4.32-4.05 (m, 8H), 3.38-3.23 (m, J=10.5, 5.3 Hz, 2H), 2.84-2.68 (m, 8H), 1.78-1.63 (m, 8H), 1.44-1.24 (m, 30H), 0.89 (t, 12H).

### Example 7. Synthesis of CzPSF

Under an argon atmosphere, the carbazolyl spirobifluorene dibromide monomer (0.3134 g, 0.25 mmol) prepared in Example 5, the carbazolyl spirobifluorene di-borate ester monomer (0.3539 g, 0.25 mmol) prepared in Example 6, tris(dibenzylideneacetone)dipalladium (Pd₂(dba)₃) (0.9 mg, 0.001 mmol), 2-dicyclohexylphosphinyl-2′,6′-dimethoxybiphenyl (S-Phos) (3.2 mg, 0.0075 mmol), trioctylmethylammonium chloride (0.1 mL), aqueous solution (2 mL) of potassium carbonate (0.55 g, 4 mmol), and dewatered and deoxygenated toluene (6 mL) were added to a reaction vessel, and heated at 96° C. with stirring for 1.5 hrs. After the completion of the reaction, the reaction solution was poured into dichloromethane, and washed sequentially with aqueous sodium chloride solution and distilled water. The organic phase was dried over anhydrous sodium sulfate, concentrated, and then dropwise added to methanol. The resulting precipitate was dried in vacuo to obtain a product. The product was identified to be CzPSF by Nuclear Magnetic Resonance (NMR). The yield was calculated to be 65%. It was analyzed by Size Exclusion Chromatography (SEC) that the number average molecular weight (Mn) was 81,000 Da and the polydispersity index (PDI) was 1.86.

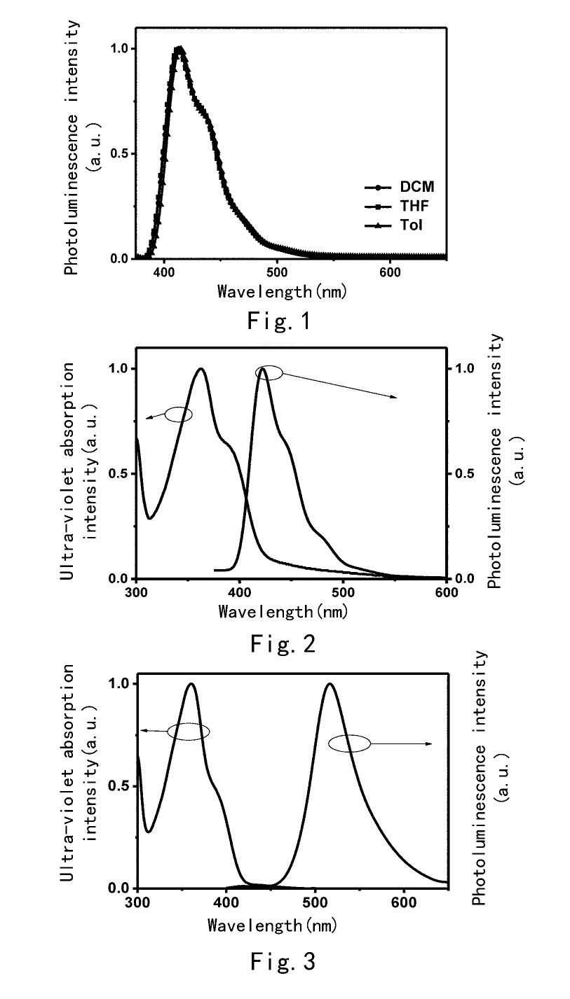

The luminescent spectrum of the CzPSF in different solvents is as shown in FIG. 1. FIG. 1 is a luminescent spectrum of the CzPSF prepared in Example 7 of the present disclosure in different solvents. As seen from FIG. 1, the luminescent spectrum of the CzPSF is not red-shifted with increased polarity of the solvent. The maximum emission is at a wavelength of 414 nm in toluene. With respect to polyfluorene as a standard, the fluorescent quantum efficiency thereof is 0.99 in toluene, and reaches 0.60 in a film form on a quartz substrate. The data are substantially consistent with the properties of polyfluorene reported in literatures, indicating that no intramolecular charge transfer from a main chain to a side chain occurs in carbazolyl poly(spirobifluorene).

The absorption and emission spectrums of the CzPSF in a film form are as shown in FIG. 2. FIG. 2 is absorption and emission spectrums of the CzPSF in a film form. As seen from FIG. 2, the maximum absorption is at a wavelength of 360 nm, and the maximum emission is at a wavelength of 422 nm. The spectrum has a dark blue light emission, which is similar to that of polyfluorene.

### Example 8. Synthesis of CzPSFDPBT05

Under an argon atmosphere, the carbazolyl spirobifluorene dibromide monomer (0.2820 g, 0.225 mmol) prepared in Example 5, the carbazolyl spirobifluorene di-borate ester monomer (0.3539 g, 0.25 mmol) prepared in Example 6, M-1 monomer (0.0111 g, 0.025 mmol), tris(dibenzylideneacetone)dipalladium (Pd₂(dba)₃) (0.9 mg, 0.001 mmol), 2-dicyclohexylphosphinyl-2′,6′-dimethoxybiphenyl (S-Phos) (3.2 mg, 0.0075 mmol), trioctylmethylammonium chloride (0.1 mL), aqueous solution (2 mL) of potassium carbonate (0.55 g, 4 mmol), and toluene (6 mL) were added to a reaction vessel, and heated at 96° C. with stirring for 1.5 hrs. After the completion of the reaction, the reaction solution was poured into dichloromethane, and washed sequentially with aqueous sodium chloride solution and distilled water. The organic phase was dried over anhydrous sodium sulfate, concentrated, and then dropwise added to methanol. The resulting precipitate was dried in vacuo to obtain a product. The product was identified to be CzPSFDPBT05 by Nuclear Magnetic Resonance (NMR). The yield was calculated to be 70%. It was analyzed by Size Exclusion Chromatography (SEC) that the number average molecular weight (Mn) was 86,000 Da and the polydispersity index (PDI) was 2.20.

FIG. 3 is absorption and emission spectrums of the CzSPFDPBT05 prepared in Example 8 of the present disclosure in a film form. As seen from FIG. 3, the maximum absorption is at a wavelength of 360 nm, and the maximum emission is at a wavelength of 517 nm, that is, the emission is a green light emission.

### Example 9. Synthesis of CzPSFDTBT05

Under an argon atmosphere, the carbazolyl spirobifluorene dibromide monomer (0.2820 g, 0.225 mmol) prepared in Example 5, the carbazolyl spirobifluorene di-borate ester monomer (0.3539 g, 0.25 mmol) of Example 6, M-2 monomer (0.0106 g, 0.025 mmol), tris(dibenzylideneacetone)dipalladium (Pd₂(dba)₃) (0.9 mg, 0.001 mmol), 2-dicyclohexylphosphinyl-2′,6′-dimethoxybiphenyl (S-Phos) (3.2 mg, 0.0075 mmol), trioctylmethylammonium chloride (0.1 mL), aqueous solution (2 mL) of potassium carbonate (0.55 g, 4 mmol), and toluene (6 mL) were added to a reaction vessel, and heated at 96° C. with stirring for 1.5 hrs. After the completion of the reaction, the reaction solution was poured into dichloromethane, and washed sequentially with aqueous sodium chloride solution and distilled water. The organic phase was dried over anhydrous sodium sulfate, concentrated, and then dropwise added to methanol. The resulting precipitate was dried in vacuo to obtain a product. The product was identified to be CzPSFDPBT05 by Nuclear Magnetic Resonance (NMR). Yield: 70%. It was analyzed by Size Exclusion Chromatography (SEC) that the number average molecular weight (Mn) was 81,000 Da and the polydispersity index (PDI) was 2.19.

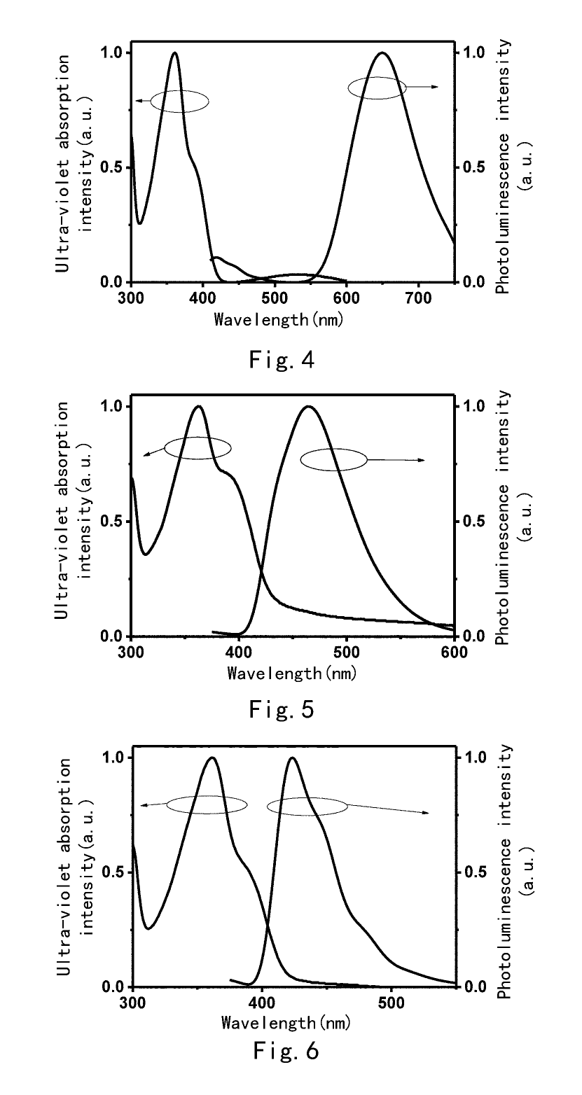

FIG. 4 is absorption and emission spectrums of the CzSPFDPBT05 prepared in Example 9 of the present disclosure in a film form. As seen from FIG. 4, the maximum absorption is at a wavelength of 360 nm, and the maximum emission is at a wavelength of 648 nm, that is, the emission is a red light emission.

### Example 10. Synthesis of CzPSF-3,7SO15

Under an argon atmosphere, the carbazolyl spirobifluorene dibromide monomer (0.2193 g, 0.175 mmol), the carbazolyl spirobifluorene di-borate ester monomer (0.3539 g, 0.25 mmol), M-3 monomer (0.0281 g, 0.0.075 mmol), tris(dibenzylideneacetone)dipalladium (Pd₂(dba)₃) (0.9 mg, 0.001 mmol), 2-dicyclohexylphosphinyl-2′,6′-dimethoxybiphenyl (S-Phos) (3.2 mg, 0.0075 mmol), trioctylmethylammonium chloride (0.1 mL), aqueous solution (2 mL) of potassium carbonate (0.55 g, 4 mmol), and toluene (6 mL) were added to a reaction vessel, and heated at 96° C. with stirring for 1.5 hrs. After the completion of the reaction, the reaction solution was poured into dichloromethane, and washed sequentially with aqueous sodium chloride solution and distilled water. The organic phase was dried over anhydrous sodium sulfate, concentrated, and then dropwise added to methanol. The resulting precipitate was dried in vacuo to obtain a product. The product was identified to be CzPSF-3,7SO15 by Nuclear Magnetic Resonance (NMR). Yield: 60%. It was analyzed by Size Exclusion Chromatography (SEC) that the number average molecular weight (Mn) was 103,000 Da and the polydispersity index (PDI) was 2.79.

FIG. 5 is absorption and emission spectrums of the CzSPF-3,7SO15 prepared in Example 10 of the present disclosure in a film form. As seen from FIG. 5, the maximum absorption is at a wavelength of 360 nm, and the maximum emission is at a wavelength of 463 nm, that is, the emission is a pure blue light emission.

### Example 11. Synthesis of CzPSF-2,8SO05

Under an argon atmosphere, the carbazolyl spirobifluorene dibromide monomer (0.2820 g, 0.225 mmol), the carbazolyl spirobifluorene di-borate ester monomer (0.3539 g, 0.25 mmol), M-4 monomer (0.0094 g, 0.025 mmol), tris(dibenzylideneacetone)dipalladium (Pd₂(dba)₃) (0.9 mg, 0.001 mmol), 2-dicyclohexylphosphinyl-2′,6′-dimethoxybiphenyl (S-Phos) (3.2 mg, 0.0075 mmol), trioctylmethylammonium chloride (0.1 mL), aqueous solution (2 mL) of potassium carbonate (0.55 g, 4 mmol), and toluene (6 mL) were added to a reaction vessel, and heated at 96° C. with stirring for 1.5 hrs. After the completion of the reaction, the reaction solution was poured into dichloromethane, and washed sequentially with aqueous sodium chloride solution and distilled water. The organic phase was dried over anhydrous sodium sulfate, concentrated, and then dropwise added to methanol. The resulting precipitate was dried in vacuo to obtain a product. The product was identified to be CzPSF-3,7SO15 by Nuclear Magnetic Resonance (NMR). Yield: 73%. It was analyzed by Size Exclusion Chromatography (SEC) that the number average molecular weight (Mn) was 86,800 Da and the polydispersity index (PDI) was 2.07.

FIG. 6 is absorption and emission spectrums of the CzSPF-2,8SO05 prepared in Example 11 of the present disclosure in a film form. As seen from FIG. 6, the maximum absorption is at a wavelength of 360 nm, and the maximum emission is at a wavelength of 423 nm, that is, the emission is a dark blue light emission.

### Example 12. Synthesis of CzPSF-2,7SSO05

Under an argon atmosphere, the carbazolyl spirobifluorene dibromide monomer (0.2820 g, 0.225 mmol), the carbazolyl spirobifluorene di-borate ester monomer (0.3539 g, 0.25 mmol), M-5 monomer (0.0135 g, 0.025 mmol), tris(dibenzylideneacetone)dipalladium (Pd₂(dba)₃) (0.9 mg, 0.001 mmol), 2-dicyclohexylphosphinyl-2′,6′-dimethoxybiphenyl (S-Phos) (3.2 mg, 0.0075 mmol), trioctylmethylammonium chloride (0.1 mL), aqueous solution (2 mL) of potassium carbonate (0.55 g, 4 mmol), and toluene (6 mL) were added to a reaction vessel, and heated at 96° C. with stirring for 1.5 hrs. After the completion of the reaction, the reaction solution was poured into dichloromethane, and washed sequentially with aqueous sodium chloride solution and distilled water. The organic phase was dried over anhydrous sodium sulfate, concentrated, and then dropwise added to methanol. The resulting precipitate was dried in vacuo to obtain a product. The product was identified to be CzPSF-3,7SO15 by Nuclear Magnetic Resonance (NMR). Yield: 75%. It was analyzed by Size Exclusion Chromatography (SEC) that the number average molecular weight (Mn) was 65,000 Da and the polydispersity index (PDI) was 2.30.

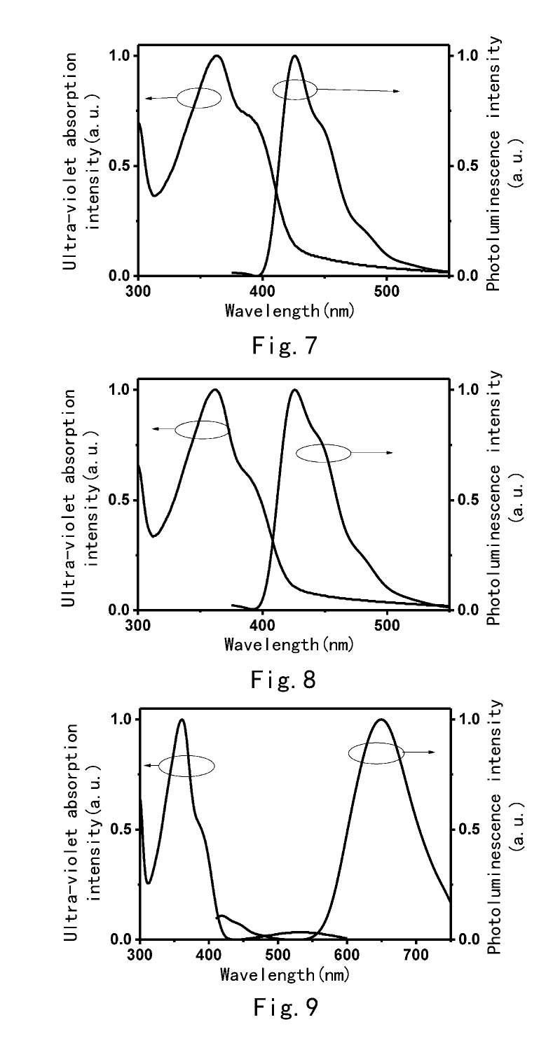

FIG. 7 is absorption and emission spectrums of the CzSPF-2,755005 prepared in Example 12 of the present disclosure in a film form. As seen from FIG. 7, the maximum absorption is at a wavelength of 360 nm, and the maximum emission is at a wavelength of 426 nm, that is, the emission is a dark blue light emission.

### Example 13. Synthesis of CzPSF-2′,7′SSO05

Under an argon atmosphere, the carbazolyl spirobifluorene dibromide monomer (0.2820 g, 0.225 mmol), the carbazolyl spirobifluorene di-borate ester monomer (0.3539 g, 0.25 mmol), M-6 monomer (0.0135 g, 0.025 mmol), tris(dibenzylideneacetone)dipalladium (Pd₂(dba)₃) (0.9 mg, 0.001 mmol), 2-dicyclohexylphosphinyl-2′,6′-dimethoxybiphenyl (S-Phos) (3.2 mg, 0.0075 mmol), trioctylmethylammonium chloride (0.1 mL), aqueous solution (2 mL) of potassium carbonate (0.55 g, 4 mmol), and toluene (6 mL) were added to a reaction vessel, and heated at 96° C. with stirring for 1.5 hrs. After the completion of the reaction, the reaction solution was poured into dichloromethane, and washed sequentially with aqueous sodium chloride solution and distilled water. The organic phase was dried over anhydrous sodium sulfate, concentrated, and then dropwise added to methanol. The resulting precipitate was dried in vacuo to obtain a product. The product was identified to be CzPSF-2′,7′SSO05 by Nuclear Magnetic Resonance (NMR). Yield: 70%. It was analyzed by Size Exclusion Chromatography (SEC) that the number average molecular weight (Mn) was 75,000 Da and the polydispersity index (PDI) was 2.45.

FIG. 8 is absorption and emission spectrums of the CzPSF-2′,7′SSO05 prepared in Example 13 of the present disclosure in a film form. As seen from FIG. 8, the maximum absorption is at a wavelength of 360 nm, and the maximum emission is at a wavelength of 426 nm, that is, the emission is a dark blue light emission.

### Example 14. Synthesis of CzPSF-3,7SO-DTBT05

Under an argon atmosphere, the carbazolyl spirobifluorene dibromide monomer (0.2005 g, 0.160 mmol), the carbazolyl spirobifluorene di-borate ester monomer (0.3539 g, 0.25 mmol), M-2 monomer (0.0063 g, 0.015 mmol), M-3 monomer (0.0281 g, 0.075 mmol), tris(dibenzylideneacetone)dipalladium (Pd₂(dba)₃) (0.9 mg, 0.001 mmol), 2-dicyclohexylphosphinyl-2′,6′-dimethoxybiphenyl (S-Phos) (3.2 mg, 0.0075 mmol), trioctylmethylammonium chloride (0.1 mL), aqueous solution (2 mL) of potassium carbonate (0.55 g, 4 mmol), and toluene (6 mL) were added to a reaction vessel, and heated at 96° C. with stirring for 1.5 hrs. After the completion of the reaction, the reaction solution was poured into dichloromethane, and washed sequentially with aqueous sodium chloride solution and distilled water. The organic phase was dried over anhydrous sodium sulfate, concentrated, and then dropwise added to methanol. The resulting precipitate was dried in vacuo to obtain a product. The product was identified to be CzPSF-3,7SO-DTBT05 by Nuclear Magnetic Resonance (NMR). Yield: 70%. It was analyzed by Size Exclusion Chromatography (SEC) that the number average molecular weight (Mn) was 85,000 Da and the polydispersity index (PDI) was 2.35.

FIG. 9 is absorption and emission spectrums of the CzPSF-3,7SO-DTBT05 prepared in Example 14 of the present disclosure in a film form. As seen from FIG. 9, the maximum absorption is at a wavelength of 360 nm, and the maximum emission is at a wavelength of 649 nm, that is, the emission is a red light emission.

### Example 15

Poly(3,4-ethylenedioxythiophene)-poly(styrenesulfonate) (PEDOT/PSS) was spin-coated onto indium tin oxide supported on a glass substrate, and annealed at 120° C. for 30 min. Then, a solution of the polymer of the present disclosure in toluene (6 mg/mL) was spin-coated at 1500 rpm for 1 min, and annealed at 80° C. for 30 min to form a 40 nm light emitting layer on the PEDOT/PSS. 2,7-bis(diphenoxyphosphinyl)-9,9′-spirobifluorene (DPSF) and aluminum cathode were sequentially deposited on the light emitting layer under a vacuum of 4×10⁻⁴ Pa to obtain an organic electroluminescent device with DPSF as the electron injection layer.

The structure of the device was PEDOT:PSS (40 nm)/EML (30 nm)/DPSF (50 nm)/LiF (1 nm)/Al (100 nm).

### Example 16

The electroluminescent device obtained in Example 15 was tested with CzPSF as the electroluminescent layer. The results are as shown in table 1.

### Example 17

The electroluminescent device obtained in Example 15 was tested with CzPSF-3,75010 as the electroluminescent layer. The results are as shown in table 1.

### Example 18

The electroluminescent device obtained in Example 15 was tested with CzPSFDPBT15 as the electroluminescent layer. The results are as shown in table 1.

### Example 19

The electroluminescent device obtained in Example 15 was tested with CzPSFDTBT03 as the electroluminescent layer. The results are as shown in table 1.

### Example 20

The electroluminescent device obtained in Example 15 was tested with CzPSF-3,7SO-DTBT05 as the electroluminescent layer. The results are as shown in table 1.

TABLE 1
Performance data for electroluminescent devices prepared in the
Examples and Comparative Examples of the present disclosure

| | | | | Maximum | |
|---|---|---|---|---|---|
| | | Maximum | | energy | |
| | Onset | current | Maximum | conversion | |
| Examples | voltage | efficiency | brightness | efficiency | Color |
| No. | [V] | [cd/A] | [cd/m²] | [%] | coordinate |
| Example 16 | 3.6 | 1.70 | 1750 | 3.0 | (0.17, 0.06) |
| Example 17 | 3.6 | 4.68 | 5470 | 3.3 | (0.16, 0.15) |
| Example 18 | 3.4 | 21.6 | 27400 | 6.0 | (0.32, 0.60) |
| Example 19 | 4.2 | 4.4 | 3250 | 4.2 | (0.61, 0.34) |
| Example 20 | 4.0 | 4.0 | 3550 | 4.2 | (0.61, 0.33) |
| Comparative | 3.2 | 2.5 | 4730 | 1.8 | (0.16, 0.15) |
| Example 1 | | | | | |
| Comparative | 4.2 | 0.54 | 1459 | 0.2 | (0.27, 0.46) |
| Example 2 | | | | | |

### Comparative Example 1

The alkoxy-modified poly(spirobifluorene) (ROPSF) having a structure represented by Formula (VI) was synthesized according to the method as disclosed in Wang Xuchao (Macromolecules, 2014, 47, 2907-2914),

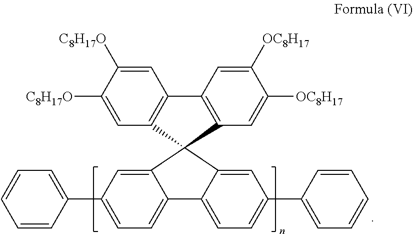

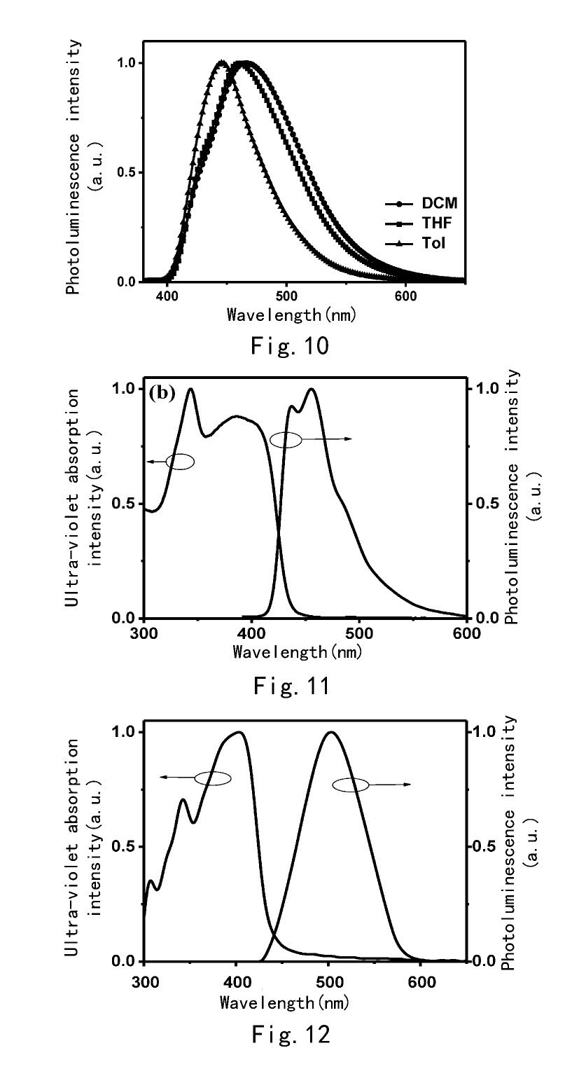

FIG. 10 is a luminescent spectrum of the ROPSF prepared in Comparative Example 1 of the present disclosure in different solvents. As seen from FIG. 10, the emission spectrum is red-shifted with increased polarity of the solvent. The maximum emission is at a wavelength of 445 nm in toluene, and is red-shifted to 469 nm in dichloromethane, displaying an apparent intramolecular charge transfer. FIG. 11 is absorption and emission spectrums of the ROPSF prepared in Comparative Example 1 in a film form. As seen from FIG. 11, the peak is at a wavelength of 455 nm in a film form, and has 33 nm red shift as compared with the CzPSF, and the spectrum is broadened obviously, evidencing the presence of charge transfer. With respect to polyfluorene as a standard, the fluorescent quantum efficiency thereof is 0.30 in toluene, and is 0.29 in a film form on a quartz substrate, which are much less than those of the carbazolyl poly(spirobifluorene) of the present disclosure (0.99 and 0.60 respectively).

The electroluminescent device obtained in Example 15 of the present disclosure was tested with ROPSF as the light emitting layer. Table 1 shows performance data for electroluminescent devices prepared in the Examples and Comparative Examples of the present disclosure. As seen from the data in the table, the ROPSF has an external quantum efficiency less than that of the CzPSF (only 0.6 times less), and the color coordinate thereof is in a pure blue light region, which is red-shifted significantly as compared with the CzPSF, confirming that the emission thereof is an intramolecular charge transfer emission.

### Comparative Example 2

A copolymer of the alkoxy poly(spirobifluorene) having a structure represented by Formula (VII) (ROPSF-3,7SO05) was synthesized according to the method as disclosed in Yang Junwei (Macromol Chem Phys, 2014, 215, 1107-1115),

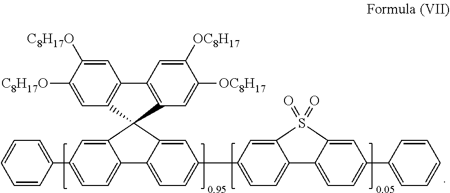

FIG. 12 is absorption and emission spectrums of the ROPSF-3,7SO05 prepared in Comparative Example 2 in a film form, wherein the emission peak wavelength is in a green light region, and is much greater than those of the CzPSF-3,7SO0 series polymers.

The device was manufactured with ROPSF-3,7SO05 as the light emitting layer. Poly(3,4-ethylenedioxythiophene)-poly(styrenesulfonate) (PEDOT/PSS) was spin-coated onto indium tin oxide supported on a glass substrate, and annealed at 120° C. for 30 min. Then, a solution of the polymer of the present disclosure in toluene (6 mg/mL) was spin-coated at 1500 rpm for 1 min, and annealed at 80° C. for 30 min to form a 40 nm light emitting layer on the PEDOT/PSS. Calcium and aluminum cathode were sequentially deposited on the light emitting layer under a vacuum of 4×10⁻⁴ Pa to obtain an organic electroluminescent device with calcium as the electron injection layer.

The structure of the device was PEDOT:PSS (40 nm)/EML (30 nm)/Calcium (50 nm)/LiF (1 nm)/Al (100 nm).

The electroluminescent device obtained in Comparative Example 2 was tested. Table 1 shows performance data for electroluminescent devices prepared in the Examples and Comparative Examples of the present disclosure. As seen from the data in the table, the external quantum efficiency of ROPSF-3,7SO05 is much less than those of the CzPSF-3,7SO series and its color coordinate is red-shifted to green region.

The above description is only some preferred embodiments of the present invention. It should be noted that some modifications and variations can be made by one of ordinary skill in the art without departing from the principle of the present invention. These modifications and variations should also be regarded as falling into the protection scope of the present invention.

1. A poly(spirobifluorene), comprising more than 50% molar ratio of a repeating unit represented by Formula (I): 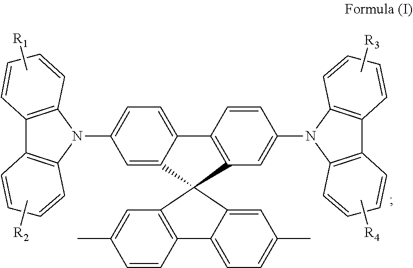
wherein R₁, R₂, R₃ and R₄ are independently selected from the group consisting of a C1˜C22 alkyl, a C1˜C22 alkoxy and a C1˜C22 heteroalkyl.

2. The poly(spirobifluorene) according to claim 1, wherein R₁, R₂, R₃ and R₄ are independently selected from the group consisting of a C3˜C15 alkyl, a C3˜C15 alkoxy and a C3˜C15 heteroalkyl;
wherein the alkyl, the alkoxy, and the heteroalkyl may be optionally substituted with a substituent selected from the group consisting of —OH, —SH, —SiH₃, —SiH₂Rₐ, —SiHRₐR_{b}, —SiRₐR_{b}R_{c}, R_{d}NH—, R_{d}RₑN—, NH₂—, a C1˜C15 alkylsulfanyl, —CO—OR_{f} and halogen; wherein the heteroalkyl contains a heteroatom of O, N, S or Si;
wherein Rₐ, R_{b}, R_{c}, R_{d}, Rₑ, and R_{f} are independently selected from the group consisting of a C1˜C22 alkyl, a C3˜C22 alkoxy, and a C1˜C22 heteroalkyl containing a heteroatom of O, N, S or Si.

3. The poly(spirobifluorene) according to claim 1, further comprising a repeating unit represented by Formula (II):
—Ar— Formula (II);
wherein Ar is selected from one or more of a C6˜C60 aryl and a C6˜C60 heteroaryl.

4. The poly(spirobifluorene) according to claim 3, wherein the aryl and heteroaryl may be optionally substituted with a substituent selected from the group consisting of H, halogen, —OH, —SH, —CN, —NO₂, a C1˜C15 alkylsulfanyl, a C1˜C40 alkyl and a C1˜C40 substituted alkyl; and
the heteroaryl contains a heteroatom independently selected from the group consisting of Si, Ge, N, P, O, S and Se.

5. The poly(spirobifluorene) according to claim 4, wherein the aryl is selected from the group consisting of a monocyclic aryl, and a combination formed by connecting a plurality of aryls via any one or more of single bond, —C—C—, —C═C—, —C═N—, —C═P—, —C≡C—, 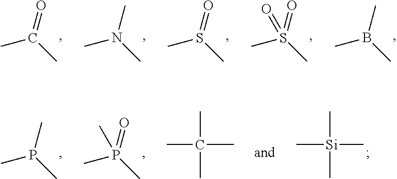
and
the heteroaryl is selected from the group consisting of a monocyclic heteroaryl, and a combination formed by connecting a plurality of heteroaryls or by connecting an aryl and a heteroaryl together, via any one or more of single bond, —C—C—, —C═C—, —C═N—, —C═P—, —C≡C—,

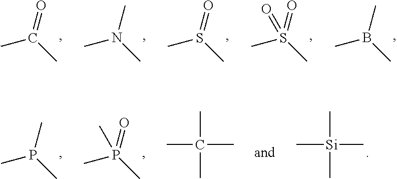

6. The poly(spirobifluorene) according to claim 5, wherein the aryl is selected from one or more of phenyl, naphthyl, anthryl, binaphthyl, phenanthryl, dihydrophenanthryl, pyrenyl, perylenyl, tetracenyl, pentacenyl, benzoperylenyl, benzocylopentadienyl, spirobifluorenyl and fluorenyl; and
the heteroaryl is one or more selected from pyrrolyl, imidazolyl, thienyl, furyl, 1,2-thiazolyl, 1,3-thiazolyl, 1,2,3-oxadiazolyl, 1,2,4-oxadiazolyl, thiadiazolyl, selenadiazolyl, 1,2,3-triazolyl, 1,2,4-triazolyl, pyridyl, pyrazinyl, pyrimidinyl, 1,3,5-triazinyl, 1,2,4-triazinyl, 1,2,3-triazinyl, indolyl, isoindolyl, benzimidazolyl, naphthoimidazolyl, phenanthroimidazolyl, benzotriazolyl, purinyl, benzoxazolyl, naphthoxazolyl, phenanthroxazolyl, benzothiadiazolyl, benzoselenadiazolyl, benzotriazolyl, quinolyl, isoquinolyl, benzopyrazinyl, benzothienyl, benzofuranyl, benzopyrrolyl, carbazolyl, acridinyl, dibenzothienyl, dibenzofuranyl, silafluorenyl, dibenzothienyl-5,5-dioxy, naphthothiadiazolyl, naphthoselenadiazolyl, and 10,15-dihydro-5H-diindolo[3,2-a:3′,2′-c]carbazolyl.

7. The poly(spirobifluorene) according to claim 3, wherein Ar has a structure represented by one of Formula (a-1) to Formula (a-8): 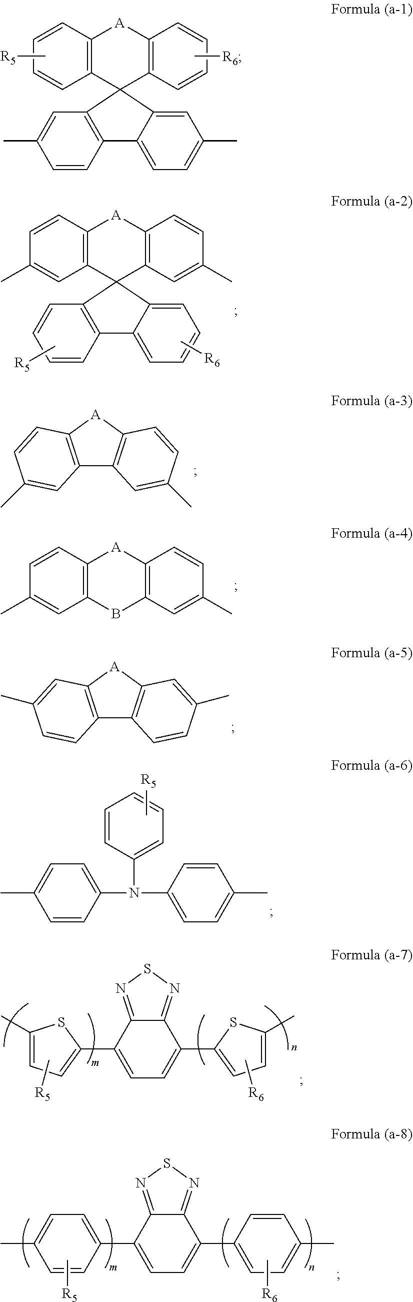
wherein A and B are independently selected from the group consisting of —CR₇R₈—, —NR₉—, —SiR₇R₈, —BR₁₀—, —O—, —S—, —SO—, —SO₂—, —PPhO— and —CO—;
wherein R₅, R₆, R₇, R₈, R₉, and R₁₀ are independently selected from the group consisting of hydrogen, a C1˜C40 alkyl, a C1˜C40 alkoxy, and a C1˜C40 heteroalkyl containing a heteroatom of O, N, S or Si; and
m and n are independently selected from the group consisting of 0, 1 and 2.

8. The poly(spirobifluorene) according to claim 7, wherein Ar has a structure represented by Formula (a-5-1), Formula (a-3-1), Formula (a-8-1), Formula (a-4-1), Formula (a-1-1), Formula (a-2-1), Formula (a-7-1), Formula (a-1-2) or Formula (a-2-2):

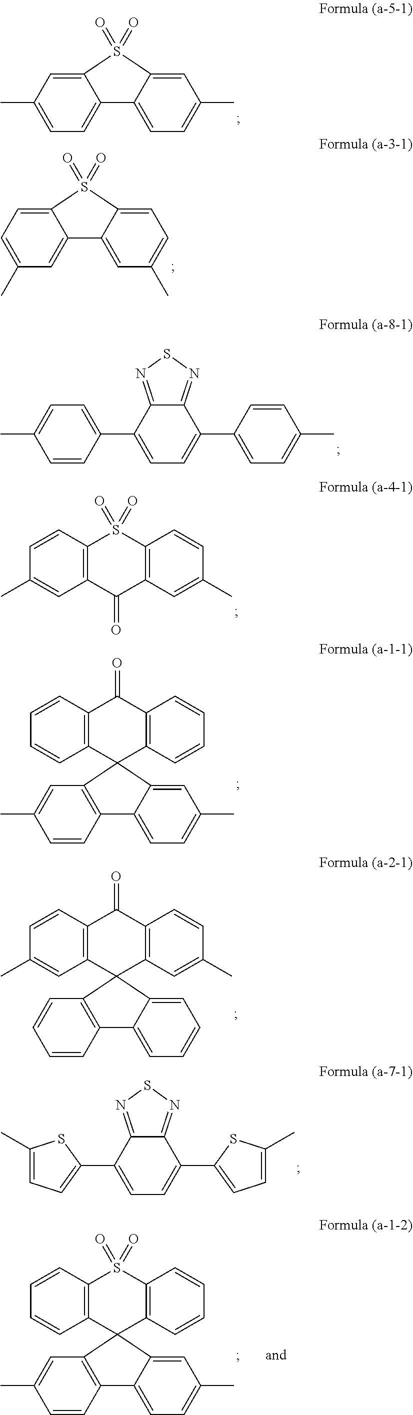

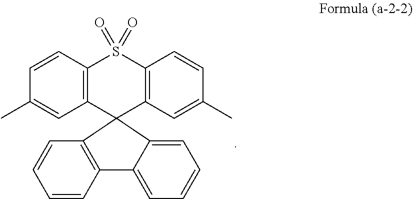

9. The poly(spirobifluorene) according to claim 8, wherein the poly(spirobifluorene) has a structure represented by one of Formula (I-1) to Formula (I-7): 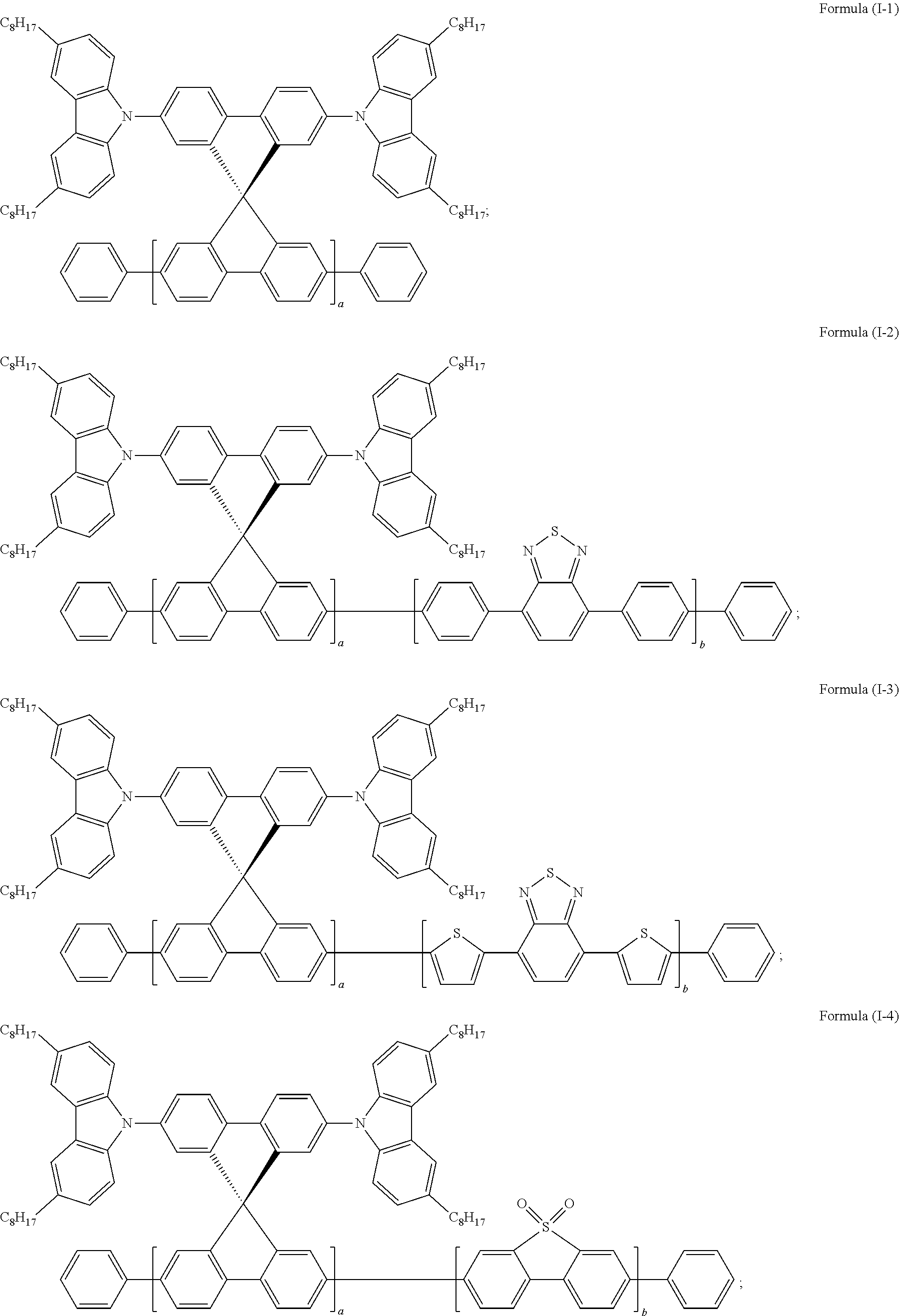 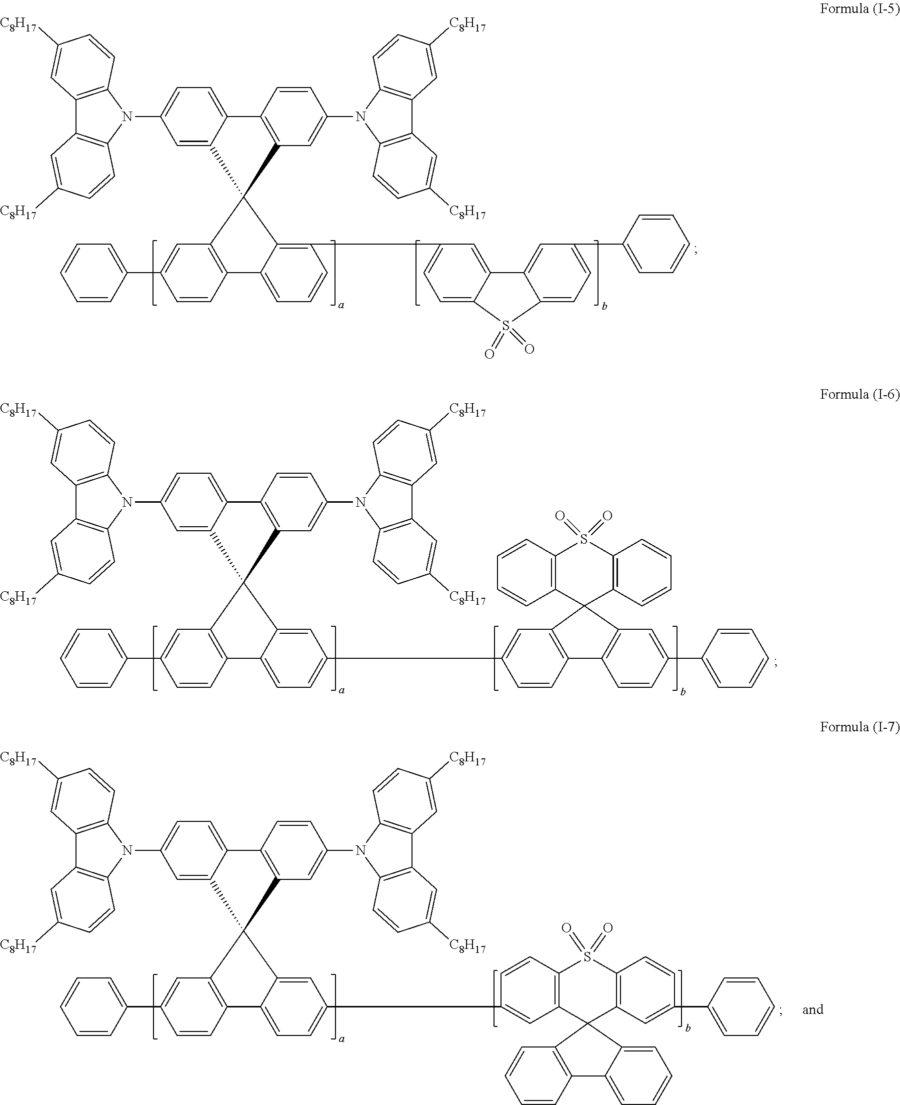 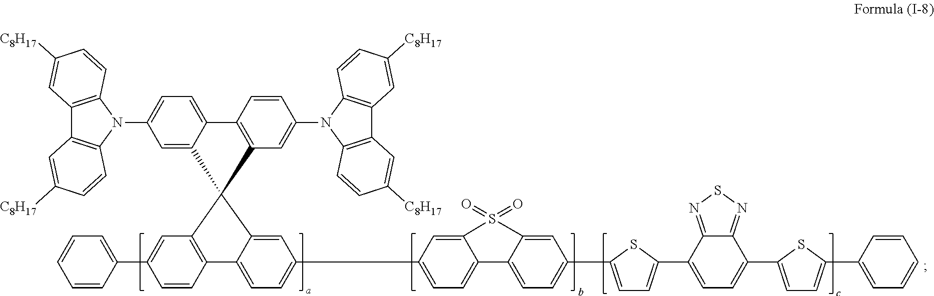
wherein 0.5<a/(a+b+c)≤1.

10. An electroluminescent device comprising a light emitting layer, wherein the light emitting layer is the poly(spirobifluorene) according to claim 1.

11. An electroluminescent device comprising a light emitting layer, wherein the light emitting layer is the poly(spirobifluorene) according to claim 2.

12. An electroluminescent device comprising a light emitting layer, wherein the light emitting layer is the poly(spirobifluorene) according to claim 3.

13. An electroluminescent device comprising a light emitting layer, wherein the light emitting layer is the poly(spirobifluorene) according to claim 4.

14. An electroluminescent device comprising a light emitting layer, wherein the light emitting layer is the poly(spirobifluorene) according to claim 5.

15. An electroluminescent device comprising a light emitting layer, wherein the light emitting layer is the poly(spirobifluorene) according to claim 6.

16. An electroluminescent device comprising a light emitting layer, wherein the light emitting layer is the poly(spirobifluorene) according to claim 7.

17. An electroluminescent device comprising a light emitting layer, wherein the light emitting layer is the poly(spirobifluorene) according to claim 8.

18. An electroluminescent device comprising a light emitting layer, wherein the light emitting layer is the poly(spirobifluorene) according to claim 9.
